(19) United States
(12) Patent Application Publication
(10) Pub. No.: US 2025/0330726 A1
(43) Pub. Date: Oct. 23, 2025

(54) PHOTOELECTRIC CONVERSION APPARATUS AND EQUIPMENT

(71) Applicant: CANON KABUSHIKI KAISHA, Tokyo (JP)

(72) Inventors: SHUHEI HAYASHI, Kanagawa (JP); YUSUKE ONUKI, Kanagawa (JP)

(21) Appl. No.: 19/092,017

(22) Filed: Mar. 27, 2025

(30) Foreign Application Priority Data
Apr. 22, 2024 (JP) 2024-069318

(51) Int. Cl. H04N 25/532; H04N 23/55; H04N 23/63; H04N 25/71; H04N 25/771; H10F 39/00

(52) U.S. Cl. CPC H04N 25/532; H04N 23/55; H04N 23/633; H04N 25/745; H04N 25/771; H10F 39/8063; H10F 39/811

(57) ABSTRACT

A global shutter type photoelectric conversion apparatus includes a first pixel and a second pixel adjacent to each other in a first direction. In the first pixel, a photoelectric conversion unit, a first charge holding unit, and a second charge holding unit are arranged to satisfy L1<L2, where L1 denotes a distance from an optical center of the photoelectric conversion unit to a centroid of the first charge holding unit, and L2 denotes a distance from the optical center of the photoelectric conversion unit to a centroid of the second charge holding unit. A photoelectric conversion unit of the second pixel, the first charge holding unit of the first pixel, and the second charge holding unit of the first pixel are arranged to satisfy L3<L4.

### BACKGROUND

### Field

The present disclosure relates to a photoelectric conversion apparatus.

### Description of the Related Art

In the field of photoelectric conversion apparatuses such as CMOS image sensors, photoelectric conversion apparatuses having a so-called global shutter function have been proposed. For example, a photoelectric conversion apparatus includes a charge holding unit that temporarily holds signal charges in each pixel, and charges are transferred from photoelectric conversion units to the charge holding units simultaneously in all the pixels. By using the global shutter function, the timing at which the photoelectric conversion units accumulate signals can be equalized in all the pixels, suppressing an image of a subject from being distorted even when the fast-moving subject is photographed.

JP 2013-172209 A proposes a technique capable of eliminating a period in which signal charges cannot be accumulated between frames and acquiring a temporally seamless moving image for a photoelectric conversion apparatus having a global shutter function. In the photoelectric conversion apparatus described in JP 2013-172209 A, two stages of charge holding units are connected to one photoelectric conversion unit. Charges generated by the photoelectric conversion unit during a certain frame are held in the earlier-stage charge holding unit during that frame, and signal charges are transferred from the earlier-stage charge holding unit to the later-stage charge holding unit at the end of that frame. The later-stage charge holding unit is used as a holding unit that holds the transferred signal charges until the transferred signal charges are converted into as an image signal and the image signal is output during the next frame.

According to the method described in JP 2013-172209 A, a moving image can be acquired by capturing consecutive frame images by a so-called global shutter operation. However, for example, when a fast-moving object is photographed in a moving image, a kind of ghost-like image may appear in front of the object in the movement direction. That is, a kind of crosstalk may occur between frames, and an image of an earlier frame may be affected by capturing an image of a later frame. This is different from a phenomenon in which an image of a later frame is affected by an image of an earlier frame, such as a so-called afterimage phenomenon.

Therefore, there has been a demand for a technology in which, an image of an earlier frame is hardly affected by capturing an image of a later frame when a moving image is captured by a global shutter operation.

### SUMMARY

According to one aspect of the present invention, a photoelectric conversion apparatus of a global shutter type includes a plurality of pixels arranged two-dimensionally on a semiconductor substrate and configured to perform photoelectric conversion operations in a same period. Each of the plurality of pixels includes a photoelectric conversion unit, a first transfer unit, a first charge holding unit, a second transfer unit, a second charge holding unit, a third transfer unit, and a signal output unit. In each of the plurality of pixels, charges generated by the photoelectric conversion unit are transferred to the first charge holding unit by the first transfer unit, the charges held in the first charge holding unit are transferred to the second charge holding unit by the second transfer unit, and the charges held in the second charge holding unit are transferred to the signal output unit by the third transfer unit. The plurality of pixels includes a first pixel and a second pixel adjacent to each other in a first direction. In the first pixel, the first charge holding unit is disposed in the first direction with respect to the photoelectric conversion unit. In the first pixel, the photoelectric conversion unit, the first charge holding unit, and the second charge holding unit are arranged to satisfy L1<L2, where L1 denotes a distance from an optical center of the photoelectric conversion unit to a centroid of the first charge holding unit, and L2 denotes a distance from the optical center of the photoelectric conversion unit to a centroid of the second charge holding unit. The photoelectric conversion unit of the second pixel, the first charge holding unit of the first pixel, and the second charge holding unit of the first pixel are arranged to satisfy L3<L4, where L3 denotes a distance from an optical center of the photoelectric conversion unit of the second pixel to the centroid of the first charge holding unit of the first pixel, and L4 denotes a distance from the optical center of the photoelectric conversion unit of the second pixel to the centroid of the second charge holding unit of the first pixel.

Further features of the present invention will become apparent from the following description of exemplary embodiments with reference to the attached drawings.

### BRIEF DESCRIPTION OF THE DRAWINGS

FIG. 1 is a block diagram illustrating a schematic configuration of a photoelectric conversion apparatus according to a first embodiment.

FIG. 2 is an equivalent circuit diagram illustrating a circuit configuration of a pixel included in the photoelectric conversion apparatus according to the first embodiment.

FIG. 3 is a timing diagram illustrating a drive sequence related to an operation of exposing the pixel.

FIG. 4 is a timing diagram illustrating a drive sequence related to an operation of reading out a signal of the pixel.

FIG. 5 is a plan view illustrating a configuration of a pixel unit formed on a semiconductor substrate of the photoelectric conversion apparatus according to the first embodiment.

FIG. 6 is a plan view for explaining a positional relationship between elements constituting the pixel in the photoelectric conversion apparatus according to the first embodiment.

FIG. 7 is a cross-sectional view illustrating a cross section of the pixel unit taken along line A-A′ in FIG. 5.

FIG. 8 is a cross-sectional view illustrating a part of a cross section of the pixel unit taken along line B-B′ in FIG. 5.

FIG. 9 is a cross-sectional view illustrating an embodiment of a back side-irradiated type image sensor.

FIG. 10 is an equivalent circuit diagram illustrating a circuit configuration of a pixel included in a photoelectric conversion apparatus according to a second embodiment.

FIG. 11 is a timing diagram illustrating a drive sequence related to an operation of reading out a signal of the pixel.

FIG. 12 is a plan view illustrating a configuration of a pixel unit formed on a semiconductor substrate of the photoelectric conversion apparatus according to the second embodiment.

FIG. 13 is a plan view for explaining a positional relationship between elements constituting the pixel in the photoelectric conversion apparatus according to the second embodiment.

FIG. 14 is a cross-sectional view illustrating a cross section of the pixel unit taken along line A-A′ in FIG. 12.

FIG. 15 is an equivalent circuit diagram illustrating a circuit configuration of a pixel included in a photoelectric conversion apparatus according to a third embodiment.

FIG. 16 is a timing diagram illustrating a drive sequence related to an operation of reading out a signal of the pixel.

FIG. 17 is a plan view illustrating a configuration of a pixel unit formed on a semiconductor substrate of the photoelectric conversion apparatus according to the third embodiment.

FIG. 18 is a plan view for explaining a positional relationship between elements constituting the pixel in the photoelectric conversion apparatus according to the third embodiment.

FIG. 19 is an equivalent circuit diagram illustrating a circuit configuration of a pixel included in a photoelectric conversion apparatus according to a fourth embodiment.

FIG. 20 is a plan view illustrating a configuration of a pixel unit formed on a semiconductor substrate of the photoelectric conversion apparatus according to the fourth embodiment.

FIG. 21 is a plan view for explaining a positional relationship between elements constituting the pixel in the photoelectric conversion apparatus according to the fourth embodiment.

FIG. 22A is a schematic diagram for explaining equipment according to a fifth embodiment.

FIG. 22B is a schematic diagram illustrating an example of a photoelectric conversion system according to the fifth embodiment.

FIG. 22C is a schematic diagram illustrating an example of an in-vehicle photoelectric conversion system according to the fifth embodiment.

### DESCRIPTION OF THE EMBODIMENTS

The inventor of the present invention has extensively studied why a kind of crosstalk occurs between frames in a conventional imaging apparatus, by which an image of an earlier frame is affected by capturing an image of a later frame, and have arrived at the following findings.

In the conventional imaging apparatus, two-stages charge holding units are connected in series with a photoelectric conversion unit of each pixel. While a photoelectric conversion signal of a current frame is being acquired using the photoelectric conversion unit and the first-stage charge holding unit, signal charges acquired in a previous frame are held in the second-stage charge holding unit. While the image of the current frame is being captured, if some of light incident on the photoelectric conversion unit of the subject pixel or the adjacent pixel leaks from the photoelectric conversion unit by diffraction, propagates through the semiconductor, and reaches the second-stage charge holding unit, photocharges may be generated there. Then, some of the photocharges of the current frame, which are not originally supposed to be added, are added to the signal charges acquired in the previous frame, resulting in a kind of crosstalk between frames. Based on such findings, the inventor of the present invention has created a structure in which light incident on the photoelectric conversion unit of the subject pixel or the adjacent pixel hardly reaches the second-stage charge holding unit.

Photoelectric conversion apparatuses according to embodiments of the present invention will be described with reference to the drawings. Note that the embodiments to be described below are exemplary, and for example, detailed configurations can be appropriately modified for implementation by those skilled in the art without departing from the gist of the present invention.

Meanwhile, it should be noted that, in the drawings referred to in the following description of embodiments, elements denoted by the same reference signs have the same functions unless otherwise specified. In the drawings, in a case where a plurality of identical elements is arranged, the reference signs and explanations thereof may be omitted.

In addition, since the drawings may be schematically represented for convenience of illustration and description, shapes, sizes, arrangements, and the like of elements illustrated in the drawings may not strictly correspond to the actual objects. In the following description, a view of a photoelectric conversion apparatus when seen through from a direction perpendicular to a main surface of a semiconductor layer may be referred to as a plan view.

### First Embodiment

A photoelectric conversion apparatus according to a first embodiment will be described with reference to the drawings. A schematic configuration of a photoelectric conversion apparatus, a circuit configuration of a pixel, and a driving method will be described first, and then a configuration of a pixel unit formed on a semiconductor substrate will be described.

### Schematic Configuration of Photoelectric Conversion Apparatus

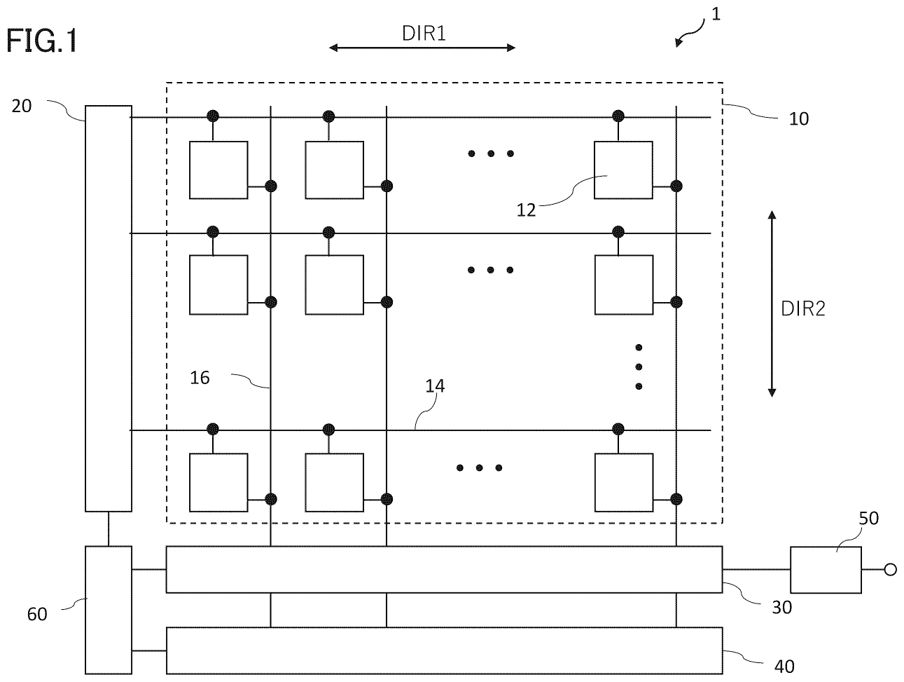

FIG. 1 is a block diagram illustrating a schematic configuration of a photoelectric conversion apparatus 1 according to the present embodiment. The photoelectric conversion apparatus 1 includes a pixel unit 10, a vertical scanning circuit 20, a readout circuit 30, a horizontal scanning circuit 40, an output circuit 50, and a control circuit 60. The pixel unit 10 is connected to the vertical scanning circuit 20 and the readout circuit 30. The readout circuit 30 is connected to the horizontal scanning circuit 40 and the output circuit 50. The control circuit 60 is connected to the vertical scanning circuit 20, the readout circuit 30, and the horizontal scanning circuit 40.

The pixel unit 10 includes a plurality of pixels 12 arranged in a matrix to form a plurality of rows and a plurality of columns. Each of the plurality of pixels 12 includes a photoelectric conversion unit constituted by a photoelectric conversion element such as a photodiode, and outputs a pixel signal corresponding to the amount of incident light. The number of rows and the number of columns of the pixel array arranged in the pixel unit 10 are not particularly limited. Note that, in the pixel unit 10, an optical black pixel of which a photoelectric conversion unit is shielded, a dummy pixel that does not output a signal, or the like may be arranged in addition to the effective pixels each outputting a pixel signal corresponding to the amount of incident light.

In the rows of the pixel unit 10, a plurality of control lines 14 extending along a row direction (a horizontal direction in FIG. 1) is arranged. Each of the control lines 14 is connected to the pixels 12 arranged in the row direction, and forms a control signal line common to these pixels 12. The row direction in which the control line 14 extends may be referred to as a horizontal direction. The control line 14 in each row is shown as one line in FIG. 1, but may include a plurality of control signal lines for each row. The control line 14 is connected to the vertical scanning circuit 20, and transmits a control signal output from the vertical scanning circuit 20 to the pixels 12. In the semiconductor substrate, the direction in which pixels commonly wired by the control line 14 are arranged (the row direction or the horizontal direction) may be referred to as a first direction DIR1. In FIG. 1, as indicated by arrows in both the left and right directions, the “first direction DIR1” may refer to a left direction or a right direction.

In the columns of the pixel unit 10, a plurality of vertical output lines 16 extending along a column direction (a vertical direction in FIG. 1) intersecting the row direction is arranged. Each of the vertical output lines 16 is connected to the pixels 12 arranged in the column direction, and forms a signal line common to the pixels 12 arranged in the column direction. The column direction in which the vertical output line 16 extends may be referred to as a vertical direction. The vertical output line 16 is connected to the readout circuit 30, and transmits a pixel signal output from the pixel 12 to the readout circuit 30. In the semiconductor substrate, the direction in which pixels commonly wired by the vertical output line 16 are arranged (the column direction or the vertical direction) may be referred to as a second direction DIR2.

The vertical scanning circuit 20 is a control circuit that functions to receive a control signal from the control circuit 60, generate a control signal for driving the pixel 12, and output the control signal to the pixel 12 via the control line 14. As the vertical scanning circuit 20, a logic circuit such as a shift register or an address decoder can be used. When reading a signal from the pixel unit 10, the vertical scanning circuit 20 outputs a control signal to the control line 14 for each row, and sequentially drives the pixels 12 of the pixel unit 10 in units of rows. The signals read out from the pixel 12 in units of rows are input to the readout circuit 30 via the vertical output line 16 arranged for each column of the pixel unit 10.

The readout circuit 30 functions to perform predetermined processing, for example, signal processing such as amplification processing or addition processing, on the signal read out from the pixel 12. The readout circuit 30 may include a signal holding unit, a column amplifier, a correlated double sampling (CDS) circuit, an addition circuit, etc. In addition, the readout circuit 30 may further include another processing circuits such as an analog/digital (A/D) conversion circuit if necessary.

The horizontal scanning circuit 40 is a control circuit that functions to receive a control signal from the control circuit 60, generate a control signal for sequentially transferring signals processed by the readout circuit 30 to the output circuit 50 for each column, and output the control signal to the readout circuit 30. As the horizontal scanning circuit 40, a logic circuit such as a shift register or an address decoder can be used.

The output circuit 50 is constituted by a buffer amplifier, a differential amplifier, or the like, and is a circuit unit for amplifying and outputting a signal output from the readout circuit 30 in which a column is selected by the horizontal scanning circuit 40. The output circuit 50 may further include a signal processing unit that performs predetermined signal processing, for example, correction processing or HDR synthesis processing, on the pixel signal.

The control circuit 60 functions to supply control signals for controlling operations and timings to the vertical scanning circuit 20, the readout circuit 30, and the horizontal scanning circuit 40. Note that at least some of the control signals supplied to the vertical scanning circuit 20, the readout circuit 30, and the horizontal scanning circuit 40 may be supplied from the outside of the photoelectric conversion apparatus 1.

### Circuit Configuration of Pixel

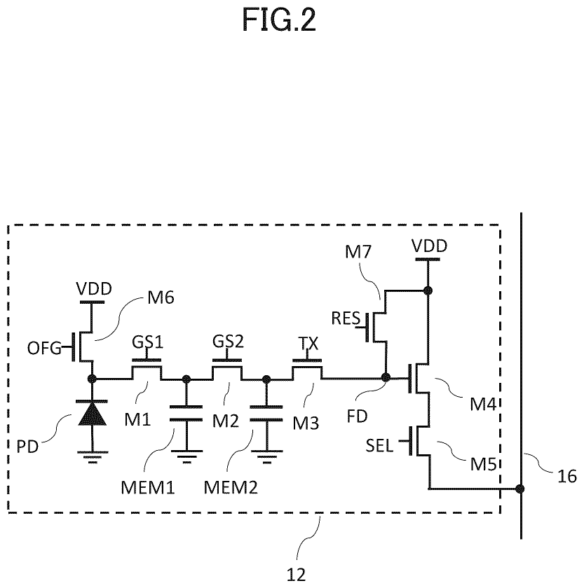

FIG. 2 is an equivalent circuit diagram illustrating a circuit configuration of the pixel 12 included in the photoelectric conversion apparatus 1 according to the present embodiment. Each of the pixels 12 includes a photoelectric conversion unit PD, a transfer transistor M1 (a first transfer unit), a transfer transistor M2 (a second transfer unit), a transfer transistor M3 (a third transfer unit), a charge holding unit MEM1 (a first charge holding unit), and a charge holding unit MEM2 (a second charge holding unit). In addition, each of the pixels 12 further includes an amplification transistor M4, a selection transistor M5, a charge discharge transistor M6, and a reset transistor M7.

The photoelectric conversion unit PD may be constituted by a photoelectric conversion element, for example, a photodiode. Each transistor may be constituted by an N-type MOS transistor, for example, in a case where electrons are used as signal charges. Note that each transistor is not necessarily an N-type MOS transistor, and each transistor may be constituted by a P-type MOS transistor, and holes may be used as signal charges.

The photoelectric conversion unit PD has an anode connected to a ground node and a cathode connected to a source of the transfer transistor M1 and a source of the charge discharge transistor M6. A drain of the transfer transistor M1 is connected to a source of the transfer transistor M2. A connection node between the drain of the transfer transistor M1 and the source of the transfer transistor M2 includes a capacitance component and functions as a first charge holding unit (a charge holding unit MEM1). A drain of the transfer transistor M2 is connected to a source of the transfer transistor M3. A connection node between the drain of the transfer transistor M2 and the source of the transfer transistor M3 includes a capacitance component and functions as a second charge holding unit (a charge holding unit MEM2).

A drain of the transfer transistor M3 is connected to a source of the reset transistor M7 and a gate of the amplification transistor M4. A connection node between the drain of the transfer transistor M3, the source of the reset transistor M7, and the gate of the amplification transistor M4 is a floating diffusion unit FD as a so-called floating diffusion unit. The floating diffusion unit FD includes a capacitance component (a floating diffusion capacitance) and functions as a charge holding unit.

A drain of the reset transistor M7, a drain of the amplification transistor M4, and a drain of the charge discharge transistor M6 are connected to a power supply voltage line (a voltage VDD). Note that two or three of the voltage supplied to the drain of the reset transistor M7, the voltage supplied to the drain of the amplification transistor M4, and the voltage supplied to the drain of the charge discharge transistor M6 may be the same, or all of them may be different. A source of the amplification transistor M4 is connected to a drain of the selection transistor M5. A source of the selection transistor M5 is connected to the vertical output line 16.

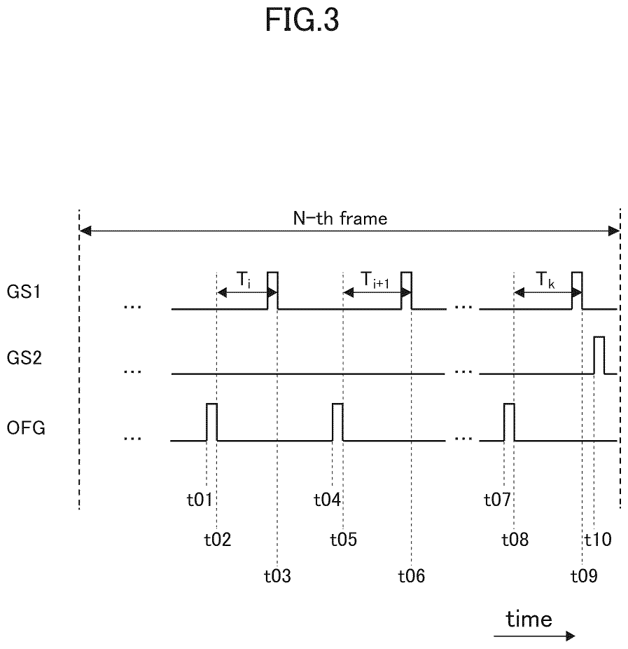

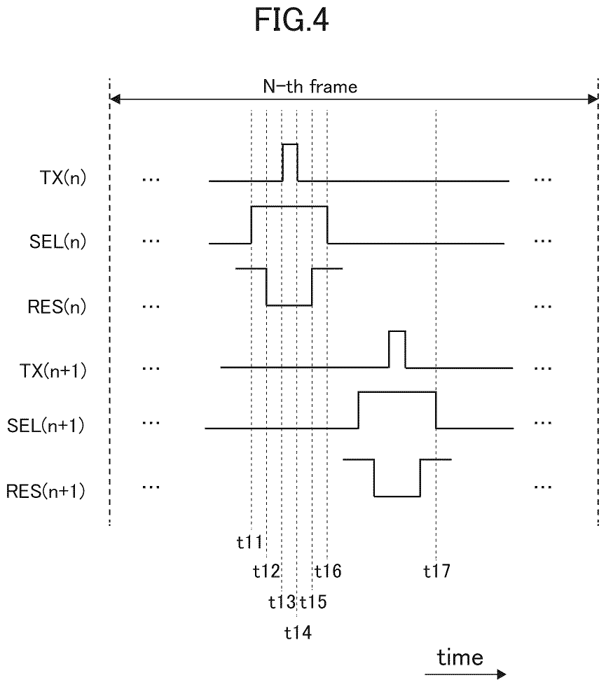

Each of the control lines 14 (FIG. 1) includes six signal lines connected to the gates of the transfer transistor M1, the transfer transistor M2, the transfer transistor M3, the reset transistor M7, the selection transistor M5, and the charge discharge transistor M6, respectively. A control signal GS1 (FIG. 3) is output from the vertical scanning circuit 20 to the signal line connected to the gate of the transfer transistor M1. A control signal GS2 (FIG. 3) is output from the vertical scanning circuit 20 to the signal line connected to the gate of the transfer transistor M2. A control signal TX (FIG. 4) is output from the vertical scanning circuit 20 to the signal line connected to the gate of the transfer transistor M3. A control signal RES (FIG. 4) is output from the vertical scanning circuit 20 to the signal line connected to the gate of the reset transistor M7. A control signal SEL (FIG. 4) is output from the vertical scanning circuit 20 to the signal line connected to the gate of the selection transistor M5. A control signal OFG (FIG. 3) is output from the vertical scanning circuit 20 to the signal line connected to the gate of the charge discharge transistor M6.

In a case where each transistor is constituted by an N-type transistor, when a high-level control signal is supplied from the vertical scanning circuit 20, the corresponding transistor is turned on, and when a low-level control signal is supplied from the vertical scanning circuit 20, the corresponding transistor is turned off. However, the conductivity type of the transistor described in the embodiment is an example, and is not limited only to the conductivity type described in the embodiment. The conductivity type can be appropriately changed from the conductivity type described in the embodiment, and the potentials of the gate, the source, and the drain of the transistor are appropriately changed in accordance with the change in conductivity type. For example, in a case where the transistor operates as a switch, the low level and the high level of the potential supplied to the gate may be reversed with respect to the description in the embodiment in accordance with the change in conductivity type.

The photoelectric conversion unit PD converts (photoelectrically converts) incident light into charges in an amount corresponding to the amount of the incident light, and accumulates the generated charges. The transfer transistor M1 is turned on to function as a transfer unit that performs a transfer operation of transferring the charges held by the photoelectric conversion unit PD to the charge holding unit MEM1. The transfer transistor M2 is turned on to function as a transfer unit that performs a transfer operation of transferring the charges held by the charge holding unit MEM1 to the charge holding unit MEM2. The transfer transistor M3 is turned on to function as a transfer unit that performs a transfer operation of transferring the charges held by the charge holding unit MEM2 to the floating diffusion unit FD.

The amplification transistor M4 constitutes an amplification unit (source follower circuit) configured such that a voltage VDD is supplied to a drain and a bias current is supplied to a source from a current source (not illustrated) via the selection transistor M5, with a gate being as an input node. As a result, the amplification transistor M4 outputs a signal corresponding to the potential of the floating diffusion unit FD to the vertical output line 16 via the selection transistor M5. In this sense, it can be said that the floating diffusion unit FD, the amplification transistor M4, and the selection transistor M5 constitute a signal output unit that outputs a signal corresponding to the amount of charges held by the floating diffusion unit FD to the vertical output line 16.

The reset transistor M7 is turned on to function as a reset unit that performs a reset operation of resetting the floating diffusion unit FD to a voltage corresponding to the voltage VDD. The charge discharge transistor M6 is turned on to function as an overflow drain unit that discharges the charges held by the photoelectric conversion unit PD. Alternatively, it can also be said that the charge discharge transistor M6 is turned on to function as a reset unit that performs a reset operation of resetting the photoelectric conversion unit PD to a voltage corresponding to the voltage VDD. The selection transistor M5 functions as a selection unit that selects whether to output a signal corresponding to the source voltage of the amplification transistor M4 to the vertical output line 16 as a pixel signal.

### Method for Driving Photoelectric Conversion Apparatus

Next, a method for driving the photoelectric conversion apparatus according to the present embodiment will be described with reference to FIGS. 3 and 4. FIG. 3 is a timing diagram illustrating a drive sequence related to an operation of exposing a pixel, and FIG. 4 is a timing diagram illustrating a drive sequence related to an operation of reading out a pixel signal.

FIG. 3 illustrates temporal changes of the control signal GS1 supplied to the transfer transistor M1, the control signal GS2 supplied to the transfer transistor M2, and the control signal OFG supplied to the charge discharge transistor M6. When each control signal is at a high level, the corresponding transistor becomes active (a turn-on state). Note that, in the present embodiment, since the global shutter type drive is performed, the drive timing related to the operation of exposing the pixel 12 is the same for the pixels 12 in all the rows. That is, the photoelectric conversion apparatus includes a plurality of pixels two-dimensionally arranged on the semiconductor substrate, performs photoelectric conversion operations on the plurality of pixels in the same period, and sequentially outputs signals for each pixel group (for each row) arranged along the first direction.

Although FIG. 4 illustrates an operation of reading out pixel signals for one frame (for an N-th frame), the drive is repeatedly performed for each frame in the same sequence to capture a moving image in the present embodiment. Note that one frame can be a period for obtaining one image. Furthermore, one frame period, which is a period for obtaining signals in one frame, can be a period from when signals in a certain pixel row are read out until signals in that row are read out again. Furthermore, in a case where the vertical scanning circuit is controlled by a vertical synchronization signal, it can be said that one frame period is a period from when the vertical synchronization signal becomes active until it becomes active again in the next time.

In the present embodiment, in each frame, the signal charge accumulation operation in an accumulation period T is executed multiple times (K times). The accumulation period T is a period for accumulating signal charges in the charge holding unit MEM1. Hereinafter, an operation from an i-th accumulation period Tᵢ to a K-th accumulation period T_{K} will be described with reference to FIG. 3. Here, i is an integer of 1 or more and K−1 or less. Note that the number of times K can be set to an appropriate number of times according to the total accumulation time or the like in one frame period.

At time t01, the vertical scanning circuit 20 controls the control signal OFG from the low level to the high level. As a result, the charge discharge transistor M6 is turned on, and the photoelectric conversion unit PD is reset to a potential corresponding to the voltage VDD.

At time t02, the vertical scanning circuit 20 controls the control signal OFG from the high level to the low level. As a result, the charge discharge transistor M6 is turned off, and the reset state of the photoelectric conversion unit PD is released. That is, the timing at which the control signal OFG transitions from the high level to the low level is a start time of the accumulation period Tᵢ in the photoelectric conversion unit PD. Signal charges generated when photons are incident on the photoelectric conversion unit PD while the charge discharge transistor M6 is turned off are accumulated in the photoelectric conversion unit PD.

In a period from a predetermined timing after time t02 to time t03, the vertical scanning circuit 20 controls the control signal GS1 to the high level. As a result, the transfer transistor M1 is turned on, and the signal charges accumulated in the photoelectric conversion unit PD are transferred to the charge holding unit MEM1. Time t03 when the transfer transistor M1 is turned off is an end time of the accumulation period Tᵢ in the photoelectric conversion unit PD. That is, a period from time t02 to time t03 is a signal charge accumulation period Tᵢ.

Next, the same operation is repeatedly performed as in the accumulation period from time t01 to time t03. For example, as illustrated in FIG. 3, an operation corresponding to an accumulation period Tᵢ₊₁ is performed during a period from time t04 to time t06, and an operation corresponding to an accumulation period T_{K} is performed during a period from time t07 to time t09.

In this manner, K accumulation periods T are executed in each frame. As a result, signal charges generated by the photoelectric conversion unit PD are held in the charge holding unit MEM1 during an accumulation period Ttotal having a length obtained by adding the lengths of the K periods from the accumulation period T₁ to the accumulation period T_{K}.

The signal charges accumulated in the charge holding unit MEM1 can be transferred to the charge holding unit MEM2 after the readout of the pixel signal based on the signal charges of the (N−1)-th frame accumulated in the charge holding unit MEM2 is completed. Here, it is assumed that the readout of the pixel signal based on the signal charges of the (N−1)-th frame accumulated in the charge holding unit MEM2 is completed by time t10.

Thereafter, in a predetermined period from time t10, the vertical scanning circuit 20 controls the control signal GS2 to the high level. As a result, the transfer transistor M2 is turned on, and the signal charges accumulated in the charge holding unit MEM1 are transferred to the charge holding unit MEM2.

When the transfer of the charges from the charge holding unit MEM1 to the charge holding unit MEM2 is completed, the charge holding unit MEM1 becomes an empty state. As a result, signal charges can be accumulated in the charge holding unit MEM1 in a next frame, that is, the (N+1)-th frame.

FIG. 4 illustrates temporal changes of the control signal TX supplied to the transfer transistor M3, the control signal SEL supplied to the selection transistor M5, and the control signal RES supplied to the reset transistor M7. When each control signal is at a high level, the corresponding transistor becomes active (a turn-on state). Here, a pixel signal readout operation is sequentially executed for each row. FIG. 4 illustrates control signals supplied to the pixels 12 in the n-th row and control signals supplied to the pixels 12 in the (n+1)-th row, among the control signals corresponding to the plurality of rows constituting the pixel unit 10. (n) is added to the reference signs for the control signals supplied to the pixels 12 in the n-th row, and (n+1) is added to the reference signs for the control signals supplied to the pixels 12 in the (n+1)-th row.

In each frame, the readout of signals based on the signal charges accumulated in the charge holding units MEM2 of the pixels 12 in each row is sequentially executed for each row. At the start time of the N-th frame, the signal charges accumulated during the accumulation period T of the (N−1)-th frame are held in the charge holding unit MEM2 of each pixel 12. It is assumed that, immediately before time t11, the control signal TX (n) and the control signal SEL(n) are at the low level, and the control signal RES(n) is at the high level.

At time t11, the vertical scanning circuit 20 switches the potential of the control signal SEL(n) from the low level to the high level. As a result, the selection transistor M5 of the pixel 12 in the n-th row is turned on, and the amplification transistor M4 of the pixel 12 in each column of the n-th row is connected to the vertical output line 16 in the corresponding column via the selection transistor M5. That is, the pixels in the n-th row are in a selected state in which signals can be read out. At this time, the reset transistor M7 is turned on, and the floating diffusion unit FD is reset to a potential corresponding to the voltage VDD. As a result, a signal corresponding to the reset potential of the floating diffusion unit FD is output to the vertical output line 16.

At subsequent time t12, the vertical scanning circuit 20 switches the potential of the control signal RES(n) from the high level to the low level. As a result, the reset transistor M7 is turned off, and the reset state of the floating diffusion unit FD is released. The voltage of the vertical output line 16 that is statically determinate after the reset transistor M7 is turned off is a reset level voltage VRES of the pixel 12. In this way, the reset level voltage VRES of the pixel 12 is read out to the vertical output line 16.

In a subsequent period from time t13 to time t14, the vertical scanning circuit 20 switches the potential of the control signal TX (n) from the low level to the high level. As a result, the transfer transistor M3 of the pixel 12 in the n-th row is turned on, and the signal charges held in the charge holding unit MEM2 are transferred to the floating diffusion unit FD. Then, the potential of the floating diffusion unit FD becomes a potential corresponding to the amount of signal charges transferred from the charge holding unit MEM2, and a voltage corresponding to the potential of the floating diffusion unit FD is output to the vertical output line 16. The voltage of the vertical output line 16 that is statically determinate after the transfer transistor M3 is turned off at time t14 is a signal level voltage VSIG of the pixel 12. In this way, the signal level voltage VSIG of the pixel 12 based on the signal charges held in the charge holding unit MEM2 is read out to the vertical output line 16.

The difference between the reset level voltage VRES and the signal level voltage VSIG obtained in this manner, that is, |VSIG−VRES|, is a physical quantity corresponding to the amount of signal charges held in the charge holding unit MEM2 (correlated double sampling).

At subsequent time t15, the vertical scanning circuit 20 switches the potential of the control signal RES(n) from the low level to the high level. As a result, the reset transistor M7 of the pixel 12 in the n-th row is turned on, and the floating diffusion unit FD is reset to a potential corresponding to the voltage VDD. A signal corresponding to the reset potential of the floating diffusion unit FD is output to the vertical output line 16.

At subsequent time t16, the vertical scanning circuit 20 switches the potential of the control signal SEL(n) from the high level to the low level. As a result, the selection transistor M5 of the pixel 12 in the n-th row is turned off, and the selection of the n-th row is released.

Furthermore, in a subsequent period from time t16 to time t17, similarly to the period from time t11 to time t16, signals are read out from the pixel 12 in the (n+1)-th row based on the signal charges accumulated in the charge holding unit MEM2. The same applies to the readout operations from the pixels 12 in the other rows.

In the present embodiment, the accumulation period Ttotal is divided into K accumulation periods T to execute the accumulation operations. By configuring the accumulation period in this manner, it is possible to suppress the time region in which signal charges are acquired from being biased within the frame and to distribute the signal charges within the frame. As a result, it is possible to suppress rattling and discontinuity of images between frames at the time of capturing a moving image as compared with those in a case of the accumulation period Ttotal is executed in one continuous period. In particular, a remarkable image quality improvement effect can be obtained when a subject moving at a high speed in a screen or a blinking light source is photographed.

Furthermore, the pixel 12 of the photoelectric conversion apparatus according to the present embodiment includes a charge holding unit that holds the signal charges of the previous frame in addition to the charge holding unit that stores signal charges. Therefore, it is possible to read out signals even during a period in which signal charges are accumulated, thereby reducing a time region in which signal charges cannot be acquired in each frame period and acquiring a seamless moving image. As described above, the method for driving the photoelectric conversion apparatus according to the present embodiment is capable of acquiring a high-quality moving image.

### Configuration of Pixel Unit

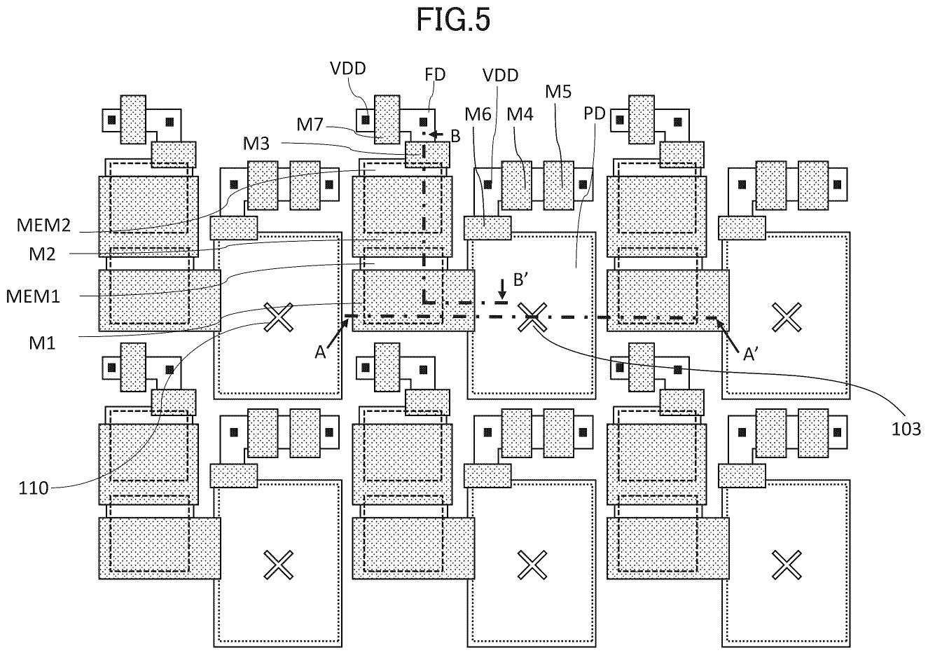

FIG. 5 is a plan view illustrating a configuration of the pixel unit formed on the semiconductor substrate in the photoelectric conversion apparatus according to the present embodiment. An active region of a semiconductor, a gate electrode, and a connection hole arranged in the active region are illustrated in a plan view from a direction orthogonal to the main surface of the semiconductor substrate. In FIG. 5, a portion of two rows and three columns is extracted from the pixel unit 10 in which a large number of pixels are arranged in a matrix. As illustrated, the pixel is arranged in a two-dimensional array with translational symmetry, and the pixels adjacent to each other have the same configurations and functions. Although FIG. 5 illustrates an example in which the pixels are arranged with one pixel being taken as a translationally symmetric unit, the pixels may be arranged with a plurality of pixels being taken as a translationally symmetric unit.

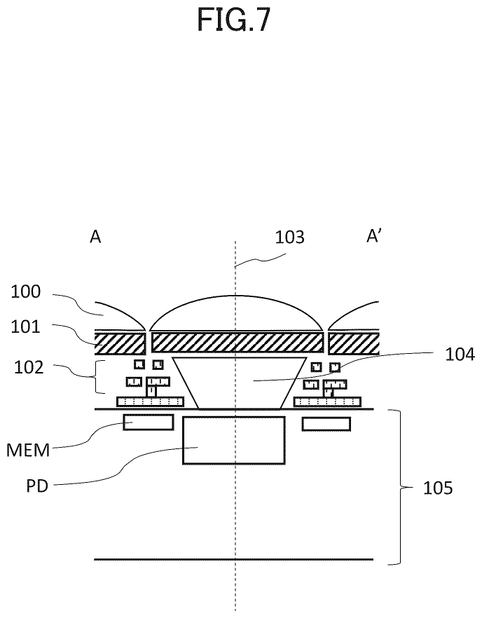

FIG. 7 is a cross-sectional view illustrating a cross section of the pixel unit 10 taken along line A-A′ in FIG. 5.

Each pixel includes a microlens 100, a color filter 101, a wiring layer 102, and a semiconductor layer 105. In the semiconductor layer 105, the photoelectric conversion unit PD and the charge holding unit MEM are formed.

The microlens 100 condenses incident light toward the optical center 103 in the photoelectric conversion unit PD, thereby contributing to improvement of sensitivity. The color filter 101 discriminates light incident on the photoelectric conversion unit PD according to a wavelength thereof, so that color information can be provided in an image signal. In the wiring layer 102, conductors such as aluminum or copper is used as wires, and signal wires such as the control line 14 and the vertical output line 16 are arranged. The metal wires are electrically disconnected from each other by an insulating film such as SiO. Furthermore, as illustrated in FIG. 7, a waveguide 104 may be provided between the color filter 101 and the photoelectric conversion unit PD. The waveguide 104 can be configured to have a refractive index different from that of the wiring layer 102 adjacent thereto to prevent light incident through the microlens 100 from leaking to the wiring layer 102, thereby enhancing the efficiency in condensing light to the photoelectric conversion unit PD.

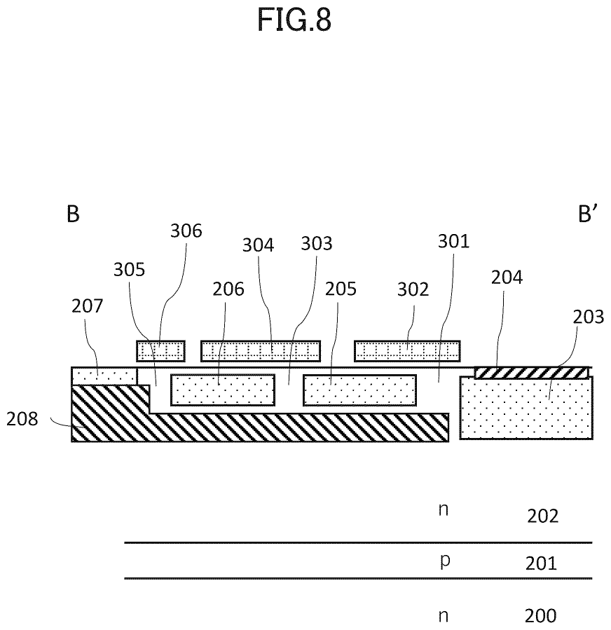

FIG. 8 is a cross-sectional view illustrating a part of a cross section of the pixel unit 10 taken along line B-B′ in FIG. 5. AP-type semiconductor region 201, an N-type semiconductor region 202, an N-type semiconductor region 203, and a P-type semiconductor region 204 are disposed on an N-type semiconductor substrate 200. The photoelectric conversion unit PD includes the P-type semiconductor region 201, the N-type semiconductor region 202, the N-type semiconductor region 203, and the P-type semiconductor region 204, and constitutes a so-called embedded photodiode.

Electrons photoelectrically converted in the N-type semiconductor region 202 and the N-type semiconductor region 203 are accumulated in the N-type semiconductor region 203. When the transfer transistor M1 is turned on, the accumulated electrons pass through a channel 301 of the transfer transistor M1 and reach an N-type semiconductor region 205 constituting the charge holding unit MEM1. The channel 301 is controlled by a gate 302 of the transfer transistor M1 disposed above the channel 301 via an insulating film.

When the transfer transistor M2 is turned on, the electrons held in the N-type semiconductor region 205 constituting the charge holding unit MEM1 move through a channel 303 of the transfer transistor M2 and reach an N-type semiconductor region 206 constituting the charge holding unit MEM2. The channel 303 is controlled by a gate 304 of the transfer transistor M2 disposed above the channel 303 via an insulating film.

When the transfer transistor M3 is turned on, the electrons held in the N-type semiconductor region 206 constituting the charge holding unit MEM2 move through a channel 305 of the transfer transistor M3 and reach an N-type semiconductor region 207 constituting the FD. The channel 305 is controlled by a gate 306 of the transfer transistor M3 disposed above the channel 305 via an insulating film.

A P-type semiconductor region 208 separates the N-type semiconductor region 202 from the N-type semiconductor region 205, the N-type semiconductor region 206, the N-type semiconductor region 207, and the like to prevent charges from being mixed with each other.

As can be seen from the cross-sectional shape of FIG. 8, the gate 302 of the transfer transistor M1 may be disposed to overlap the N-type semiconductor region 205 constituting the charge holding unit MEM1 in plan view. As a result, when the transfer transistor M1 is turned on, that is, when charges are transferred from the photoelectric conversion unit PD to the charge holding unit MEM1, the potential of the charge holding unit MEM1 can be raised, making it easy to completely transfer the charges to the charge holding unit MEM1.

Furthermore, as can be seen from the cross-sectional shape of FIG. 8, the gate 304 of the transfer transistor M2 may be disposed to overlap the N-type semiconductor region 206 constituting the charge holding unit MEM2 in plan view. As a result, when the transfer transistor M2 is turned on, that is, when charges are transferred from the charge holding unit MEM1 to the charge holding unit MEM2, the potential of the charge holding unit MEM2 can be raised, making it easy to completely transfer the charges to the charge holding unit MEM2.

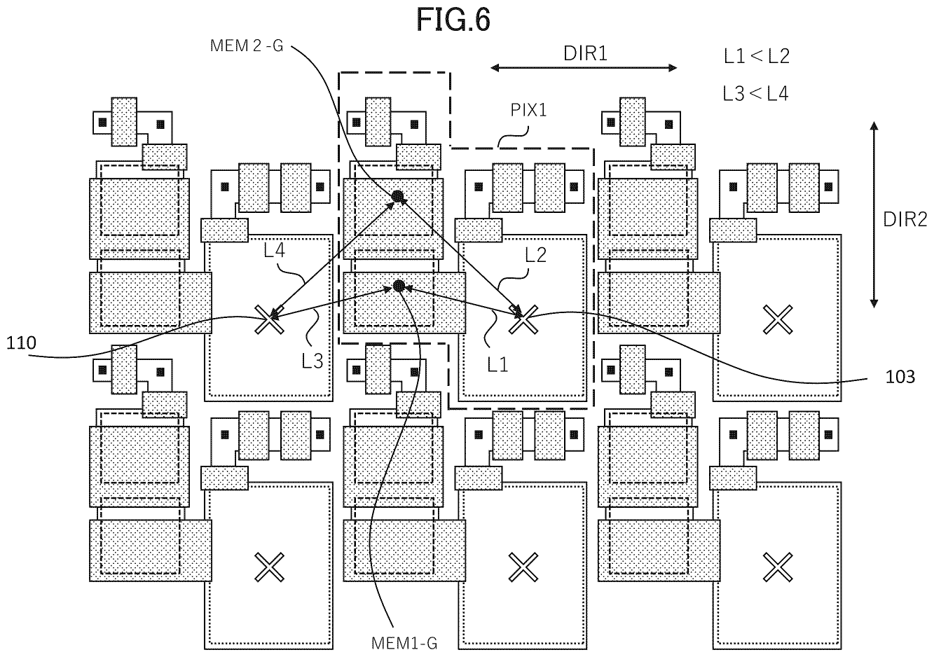

FIG. 6 is a view for explaining a positional relationship between elements constituting a pixel, and is a plan view in which dimension lines and the like are added to FIG. 5 while omitting reference signs and the like from FIG. 5. The direction in which pixels commonly wired by the control line 14 in FIG. 1 are arranged (the row direction or the horizontal direction) is illustrated as a first direction DIR1 in FIG. 6. In FIG. 6, as indicated by arrows in both the left and right directions, the “first direction DIR1” may refer to a left direction or a right direction. In addition, the direction in which pixels commonly wired by the vertical output line 16 in FIG. 1 are arranged (the column direction or the vertical direction) is illustrated as a second direction DIR2 in FIG. 6. Unlike the directions illustrated in FIG. 6, the direction in which pixels commonly wired by the control line 14 in FIG. 1 are arranged (the row direction or the horizontal direction) may be the second direction DIR2, and the direction in which pixels commonly wired by the vertical output line 16 in FIG. 1 are arranged (the column direction or the vertical direction) may be the first direction DIR1. In the following description, description will be given focusing on a pixel PIX1 surrounded by a dotted line, but since each pixel is arranged in a translationally symmetric manner, it can be said that the same applies to the other pixels.

The optical center of the photoelectric conversion unit PD of the pixel PIX1 is defined as an optical center 103, the centroid position of the charge holding unit MEM1 (the first charge holding unit) in plan view is defined as a centroid position MEM1-G, and the centroid position of the charge holding unit MEM2 (the second charge holding unit) in plan view is defined as a centroid position MEM2-G. Furthermore, the optical center of the photoelectric conversion unit PD of the pixel (the second pixel) adjacent to the pixel PIX1 (the first pixel) in the first direction DIR1 (the left direction in FIG. 6) is defined as an optical center 110.

In the pixel PIX1, the charge holding unit MEM1 is disposed in the first direction DIR1 (the left direction in FIG. 6) with respect to the photoelectric conversion unit PD. Here, the arrangement in the first direction DIR1 means that at least a part of the charge holding unit MEM1 and at least a part of the photoelectric conversion unit PD are arranged adjacent to each other in the first direction DIR1. Alternatively, the arrangement in the first direction DIR1 means that any straight line parallel to the first direction DIR1 intersects both at least a part of the charge holding unit MEM1 and at least a part of the photoelectric conversion unit PD.

In the present embodiment, when a distance between the optical center 103 and the centroid position MEM1-G in plan view is defined as L1, and a distance between the optical center 103 and the centroid position MEM2-G in plan view is defined as L2, L1<L2 is satisfied. In addition, when a distance between the optical center 110 of the adjacent pixel and the centroid position MEM1-G in plan view is defined as L3, and a distance between the optical center 110 of the adjacent pixel and the centroid position MEM2-G in plan view is defined as L4, L3<L4 is satisfied.

As described above, the charge holding unit MEM1 is used to hold signal charges generated during the N-th frame period in the photoelectric conversion unit PD only in the N-th frame. Furthermore, the charge holding unit MEM2 is used to hold signal charges of the (N−1)-th frame until the signal charges acquired in the (N−1)-th frame, which is the previous frame, are transferred to the floating diffusion unit FD and read out through the amplification transistor M4 while the N-th frame is photographed.

For example, consider a case where stronger light is incident on the pixel PIX1 during the N-th frame period as compared with that during the (N−1)-th frame period. Some of the strong light incident on the photoelectric conversion unit PD of the pixel PIX1 may be diffracted in the semiconductor and leak out of the photoelectric conversion unit PD as stray light. If such stray light easily reaches the charge holding unit MEM2, photocharges are generated in the charge holding unit MEM2 due to the stray light and superimposed on the signal charges of the previous frame held in the charge holding unit MEM2.

That is, some of the photocharges of the current frame, which are not originally supposed to be added, are added to the signal charges acquired in the previous frame and held by the charge holding unit MEM2, resulting in a kind of crosstalk between frames.

Alternatively, when strong light is incident on the pixel adjacent to the pixel PIX1 in the first direction DIR1 during the N-th frame period, some of the strong light incident on the photoelectric conversion unit PD of the adjacent pixel may be diffracted in the semiconductor and leaked out of the photoelectric conversion unit PD as stray light. If such stray light easily reaches the charge holding unit MEM2 of the pixel PIX1, photocharges are generated in the charge holding unit MEM2 due to the stray light and superimposed on the signal charges of the previous frame held in the charge holding unit MEM2. That is, some of the photocharges of the adjacent pixel of the current frame, which are not originally supposed to be added, are added to the signal charges acquired in the previous frame and held by the charge holding unit MEM2, resulting in a kind of crosstalk between frames.

The stray light attenuates exponentially according to the traveling distance in the semiconductor. According to the present embodiment, since L1<L2 is satisfied, the stray light leaking from the photoelectric conversion unit PD of the pixel PIX1 hardly reaches the charge holding unit MEM2. Furthermore, according to the present embodiment, since L3<L4 is satisfied, stray light leaking from the photoelectric conversion unit PD of the adjacent pixel in the first direction DIR1 hardly reaches the charge holding unit MEM2 of the pixel PIX1.

Therefore, the photoelectric conversion apparatus according to the present embodiment is capable of acquiring a high-quality moving image because an image of an earlier frame is hardly affected by capturing an image of a later frame when a moving image is captured by a global shutter operation.

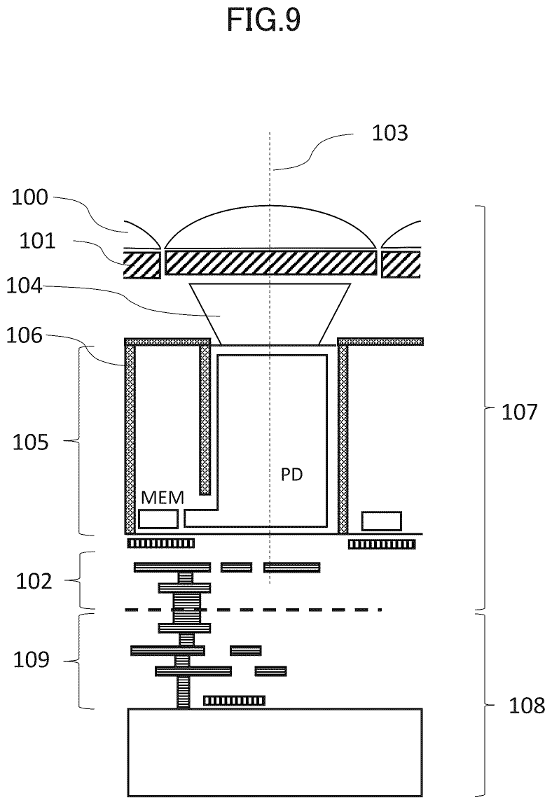

Note that although an example of a so-called front side incident-type image sensor is illustrated in FIG. 7, the embodiment is not limited thereto, and for example, a back-illuminated image sensor, of which a cross section is illustrated in FIG. 9, may be used. In the example of FIG. 7, the wiring layer 102 is disposed between the microlens 100 and the photoelectric conversion unit PD, but as in the example of FIG. 9, the wiring layer may be disposed opposite to the microlens with the semiconductor layer 105 including the photoelectric conversion unit PD interposed therebetween.

In the example illustrated in FIG. 7, the waveguide 104 serving as a light incidence path is disposed in a region adjacent to the wiring layer 102, which restricts a space for arranging the wiring layer 102. In the example of FIG. 9, since the wiring layer 102 is disposed opposite to the microlens, the space restriction is eliminated, and the degree of freedom in wiring layout is improved. There is an effect in that the number of drive lines and signal lines can be increased to improve the functions, or the parasitic capacitance between the wires can be reduced to improve the characteristics.

A light shielding portion 106 formed of, for example, a metal may be provided in a semiconductor substrate 107. The light shielding portion 106 is disposed to surround at least a part of the periphery of the charge holding unit MEM1 and/or the charge holding unit MEM2, and suppresses entry of incident light into the charge holding unit as stray light.

Furthermore, as illustrated in FIG. 9, a laminated sensor in which the first semiconductor substrate 107 including the photoelectric conversion unit PD and the microlens 100 and the second semiconductor substrate 108 are laminated may be used. Since circuits can also be arranged on the second semiconductor substrate 108 and the circuit density per area can be improved, the functions can be improved and the chip area can be reduced. A wiring layer 109 in the second semiconductor substrate 108 is electrically connected to the wiring layer 102 in the first semiconductor substrate to constitute an electronic circuit.

Even in such a back-illuminated image sensor, according to the present embodiment, since L1<L2 is satisfied, stray light leaking from the photoelectric conversion unit PD of the pixel PIX1 hardly reaches the charge holding unit MEM2. Furthermore, according to the present embodiment, since L3<L4 is satisfied, stray light leaking from the photoelectric conversion unit PD of the adjacent pixel in the first direction DIR1 hardly reaches the charge holding unit MEM2 of the pixel PIX1. Therefore, when a moving image is captured by a global shutter operation, an image of an earlier frame is hardly affected by capturing an image of a later frame, thereby making it possible to acquire a high-quality moving image.

### Second Embodiment

A photoelectric conversion apparatus according to a second embodiment will be described with reference to the drawings. The description of matters common to the first embodiment will be simplified or omitted. A schematic configuration of the photoelectric conversion apparatus is similar to that in the first embodiment described with reference to FIG. 1. In the second embodiment, a circuit configuration of a pixel, and a driving method will be described, and then a configuration of a pixel unit formed on a semiconductor substrate will be described.

### Circuit Configuration of Pixel

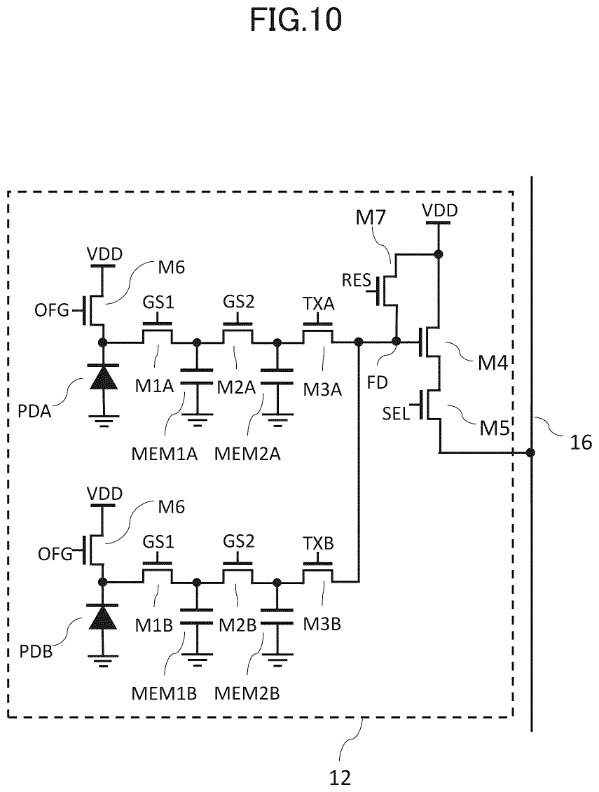

FIG. 10 is an equivalent circuit diagram illustrating a circuit configuration of a pixel 12 included in the photoelectric conversion apparatus according to the present embodiment. Each pixel 12 included in the photoelectric conversion apparatus according to the present embodiment includes two sets of circuit blocks each including one photoelectric conversion unit, three transfer transistors, two charge holding units, and one charge discharge transistor. Furthermore, each pixel 12 includes a floating diffusion unit FD, a reset transistor M7, an amplification transistor M4, and a selection transistor M5 shared by these two sets of circuit blocks.

The first set of circuit blocks includes a photoelectric conversion unit PDA (a first photoelectric conversion unit), a transfer transistor MIA (a first transfer unit), a transfer transistor M2A (a second transfer unit), a transfer transistor M3A (a third transfer unit), a charge holding unit MEM1A (a first charge holding unit), a charge holding unit MEM2A (a second charge holding unit), and a charge discharge transistor M6. In addition, the second set of circuit blocks includes a photoelectric conversion unit PDB (a second photoelectric conversion unit), a transfer transistor MIB (a fourth transfer unit), a transfer transistor M2B (a fifth transfer unit), a transfer transistor M3B (a sixth transfer unit), a charge holding unit MEM1B (a third charge holding unit), a charge holding unit MEM2B (a fourth charge holding unit), and a charge discharge transistor M6.

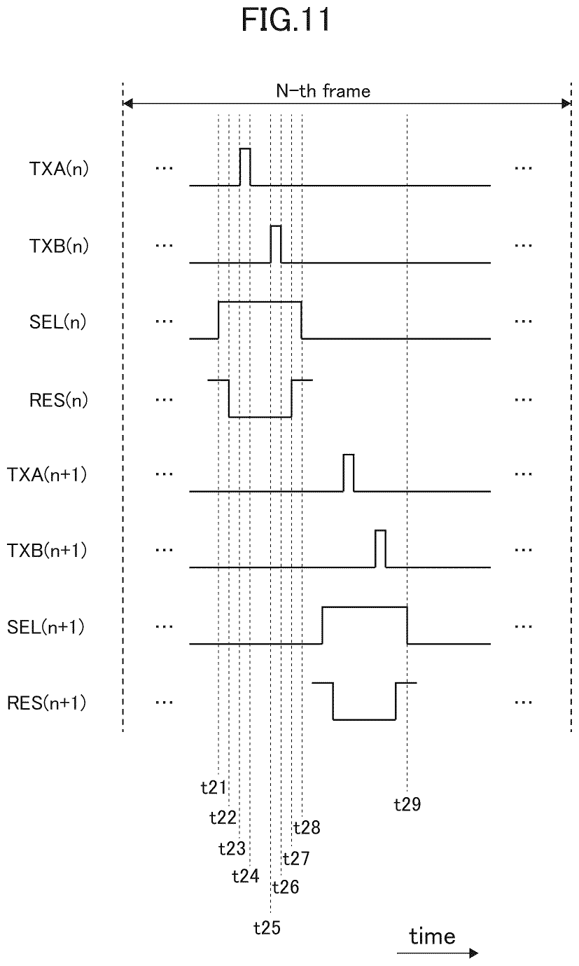

The control line 14 connected to each pixel from the vertical scanning circuit 20 (FIG. 1) includes a total of seven signal lines per pixel. A control signal GS1 (FIG. 3) is output from the vertical scanning circuit 20 to the gates of the transfer transistor MIA and the transfer transistor M1B, and a control signal GS2 (FIG. 3) is output to the gates of the transfer transistor M2A and the transfer transistor M2B. A control signal OFG (FIG. 3) is output to the gates of the two charge discharge transistors M6. A control signal TXA (which will described below with reference to FIG. 11) is output from the vertical scanning circuit 20 to the gate of the transfer transistor M3A, and a control signal TXB is output from the vertical scanning circuit 20 to the gate of the transfer transistor M3B. In a case where each transistor is constituted by an N-type transistor, when a high-level control signal is supplied from the vertical scanning circuit 20, the corresponding transistor is turned on, and when a low-level control signal is supplied from the vertical scanning circuit 20, the corresponding transistor is turned off.

Each of the photoelectric conversion unit PDA and the photoelectric conversion unit PDB convert (photoelectrically convert) incident light into charges in an amount corresponding to the amount of light, and accumulate the generated charges. The transfer transistor MIA is turned on to function as a transfer unit that performs a transfer operation of transferring the charges held by the photoelectric conversion unit PDA to the charge holding unit MEM1A. The transfer transistor MIB is turned on to function as a transfer unit that performs a transfer operation of transferring the charges held by the photoelectric conversion unit PDB to the charge holding unit MEM1B. The transfer transistor M2A is turned on to function as a transfer unit that performs a transfer operation of transferring the charges held by the charge holding unit MEM1A to the charge holding unit MEM2A. The transfer transistor M2B is turned on to function as a transfer unit that performs a transfer operation of transferring the charges held by the charge holding unit MEM1B to the charge holding unit MEM2B. The transfer transistor M3A is turned on to function as a transfer unit that performs a transfer operation of transferring the charges held by the charge holding unit MEM2A to the floating diffusion unit FD. The transfer transistor M3B is turned on to function as a transfer unit that performs a transfer operation of transferring the charges held by the charge holding unit MEM2B to the floating diffusion unit FD. The functions and operations of the reset transistor M7, the amplification transistor M4, the selection transistor M5, and the charge discharge transistor M6 are similar to those in the first embodiment.

### Method for Driving Photoelectric Conversion Apparatus

Next, a method for driving the photoelectric conversion apparatus according to the present embodiment will be described with reference to FIG. 11. FIG. 11 is a timing chart illustrating a drive related to an operation of reading out a signal of a pixel.

FIG. 11 illustrates the control signal TXA supplied to the transfer transistor M3A, the control signal TXB supplied to the transfer transistor M3B, the control signal SEL supplied to the selection transistor M5, and the control signal RES supplied to the reset transistor M7. The operation of reading out pixel signals from the plurality of rows constituting the pixel unit 10 is sequentially executed for each row, and FIG. 11 illustrates control signals supplied to the pixels 12 in the n-th row and control signals supplied to the pixels 12 in the (n+1)-th row. (n) is added to the reference signs for the control signals supplied to the pixels 12 in the n-th row, and (n+1) is added to the reference signs for the control signals supplied to the pixels 12 in the (n+1)-th row. When each control signal is at a high level, the corresponding transistor becomes active (a turn-on state).

In each frame, the readout of signals to the vertical output line 16 based on the signal charges accumulated in the charge holding units MEM2A and the charge holding units MEM2B of the pixels 12 in each row is sequentially executed for each row. At the start time of the N-th frame, the signal charges accumulated during the accumulation period T of the (N−1)-th frame are held in each of the charge holding unit MEM2A and the charge holding unit MEM2B of each pixel 12.

It is assumed that, immediately before time t21, the control signal TXA(n), the control signal TXB(n), and the control signal SEL(n) are at a low level, and the control signal RES(n) is at a high level.

At time t21, the vertical scanning circuit 20 controls the control signal SEL(n) from the low level to the high level. As a result, the selection transistor M5 of the pixel 12 in the n-th row is turned on, and the amplification transistor M4 and the vertical output line 16 in the corresponding column are connected via the selection transistor M5 of the pixel 12 in each column of the n-th row, so that the pixel is in a selected state in which a pixel signal can be read out. At this time, the reset transistor M7 is turned on, and the floating diffusion unit FD is reset to a potential corresponding to the voltage VDD. As a result, a signal corresponding to the reset potential of the floating diffusion unit FD is output to the vertical output line 16.

At subsequent time t22, the vertical scanning circuit 20 controls the control signal RES(n) from the high level to the low level. As a result, the reset transistor M7 is turned off, and the reset state of the floating diffusion unit FD is released. The voltage of the vertical output line 16 that is statically determinate after the reset transistor M7 is turned off is a reset level voltage VRES of the pixel 12. In this way, the reset level voltage VRES of the pixel 12 is read out to the vertical output line 16.

In a subsequent period from time t23 to time t24, the vertical scanning circuit 20 controls the control signal TXA(n) from the low level to the high level. As a result, the transfer transistor M3A of the pixel 12 in the n-th row is turned on, and the signal charges held in the charge holding unit MEM2A are transferred to the floating diffusion unit FD. Then, the potential of the floating diffusion unit FD becomes a potential corresponding to the amount of signal charges transferred from the charge holding unit MEM2A, and a voltage corresponding to the potential of the floating diffusion unit FD is output to the vertical output line 16. The voltage of the vertical output line 16 that is statically determinate after the transfer transistor M3A is turned off at time t24 is a signal level voltage VSIG1 of the pixel 12. In this way, the signal level voltage VSIG1 of the pixel 12 based on the signal charges held in the charge holding unit MEM2A is read out to the vertical output line 16.

In a subsequent period from time t25 to time t26, the vertical scanning circuit 20 controls the control signal TXB(n) from the low level to the high level. As a result, the transfer transistor M3B of the pixel 12 in the n-th row is turned on, and the signal charges held in the charge holding unit MEM2B are transferred to the floating diffusion unit FD. Then, the potential of the floating diffusion unit FD becomes a potential corresponding to the amount of signal charges transferred from the charge holding unit MEM2B in addition to the signal charges already transferred from the charge holding unit MEM2A. A voltage corresponding to the potential of the floating diffusion unit FD is output to the vertical output line 16. The voltage of the vertical output line 16 that is statically determinate after the transfer transistor M3B is turned off at time t26 is a signal level voltage VSIG2 of the pixel 12. In this way, the signal level voltage VSIG2 of the pixel 12 based on the signal charges held in the charge holding units MEM2A and MEM2B is read out to the vertical output line 16.

The difference between the reset level voltage VRES and the signal level voltage VSIG2 obtained in this manner, that is, |VSIG2−VRES|, is a physical quantity corresponding to the total amount of signal charges held in the charge holding unit MEM2A and the charge holding unit MEM2B.

At subsequent time t27, the vertical scanning circuit 20 controls the control signal RES(n) from the low level to the high level. As a result, the reset transistor M7 of the pixel 12 in the n-th row is turned on, and the floating diffusion unit FD is reset to a potential corresponding to the voltage VDD. A signal corresponding to the reset potential of the floating diffusion unit FD is output to the vertical output line 16.

At subsequent time t28, the vertical scanning circuit 20 controls the control signal SEL(n) from the high level to the low level. As a result, the selection transistor M5 of the pixel 12 in the n-th row is turned off, and the selection of the n-th row is released.

Furthermore, in a subsequent period up to time t29, signals are read out from the pixel 12 in the (n+1)-th row based on the signal charges accumulated in the charge holding unit MEM2A and the charge holding unit MEM2B in a procedure similar to that for the readout of the n-th row performed in the period from time t21 to time t28. The readout of signals from the pixels 12 in the other rows is also sequentially performed in units of rows in a similar procedure.

### Configuration of Pixel Unit

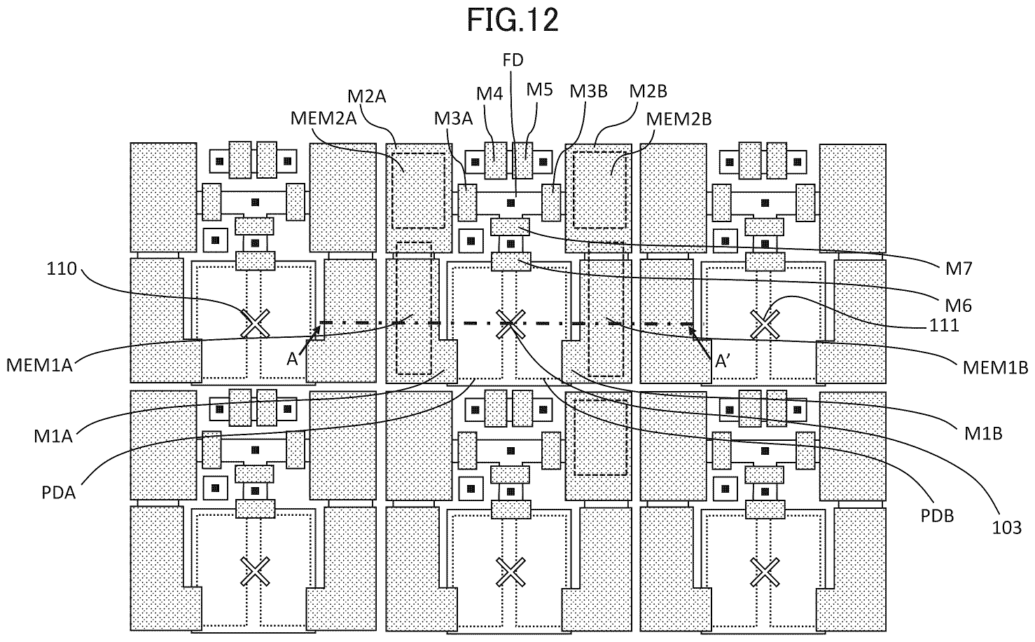

FIG. 12 is a plan view illustrating a configuration of the pixel unit formed on the semiconductor substrate in the photoelectric conversion apparatus according to the present embodiment. An active region of a semiconductor, a gate electrode, and a connection hole arranged in the active region are illustrated in a plan view from a direction orthogonal to the main surface of the semiconductor substrate. In FIG. 12, a portion of two rows and three columns is extracted from the pixel unit 10 in which a large number of pixels are arranged in a matrix. As illustrated, the pixel is arranged in a two-dimensional array with translational symmetry, and the pixels adjacent to each other have the same configurations and functions. Although FIG. 12 illustrates an example in which the pixels are arranged in a translationally symmetric manner with one pixel being taken as a unit, the pixels may be arranged in a translationally symmetric manner with a plurality of pixels being taken as a unit.

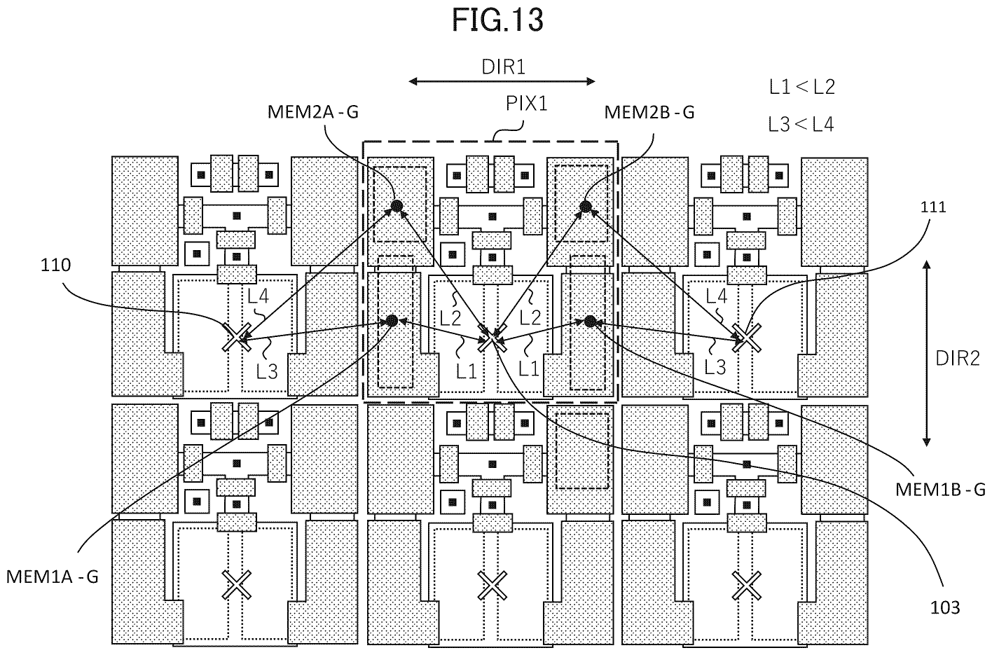

The arrangement relationship between the photoelectric conversion unit PDA (the first photoelectric conversion unit), the transfer transistor MIA (the first transfer unit), the transfer transistor M2A (the second transfer unit), the transfer transistor M3A (the third transfer unit), the charge holding unit MEM1A (the first charge holding unit), the charge holding unit MEM2A (the second charge holding unit), the photoelectric conversion unit PDB (the second photoelectric conversion unit), the transfer transistor M1B (the fourth transfer unit), the transfer transistor M2B (the fifth transfer unit), the transfer transistor M3B (the sixth transfer unit), the charge holding unit MEM1B (the third charge holding unit), and the charge holding unit MEM2B (the fourth charge holding unit) will be described below with reference to FIG. 13.

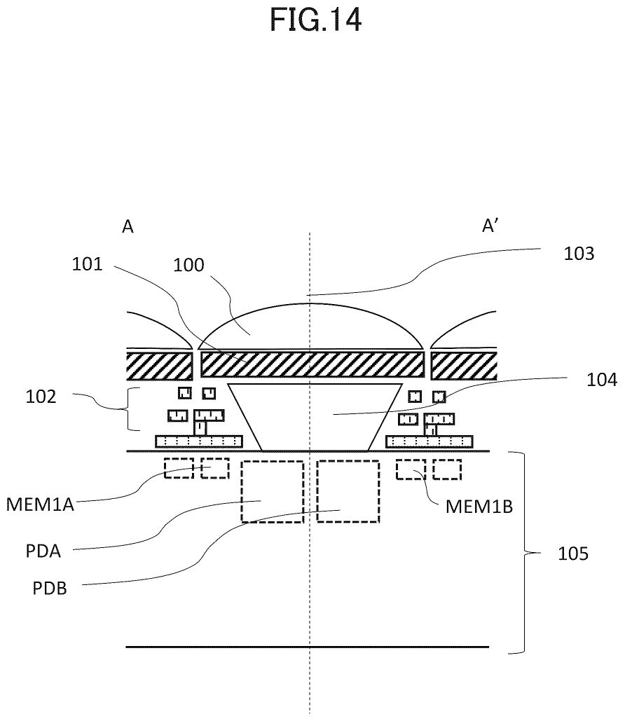

FIG. 14 is a cross-sectional view illustrating a cross section of the pixel unit 10 taken along line A-A′ in FIG. 12. As illustrated in FIG. 14, the photoelectric conversion unit PDA and the photoelectric conversion unit PDB constituting one pixel 12 share one microlens 100. In other words, the photoelectric conversion unit PDA and the photoelectric conversion unit PDB are configured to receive light that has passed through different pupil regions out of the light incident on the imaging optical system. That is, the microlens 100 condenses light having passed through a first pupil region of the exit pupil of the imaging lens on the photoelectric conversion unit PDA, and condenses light having passed through a second pupil region different from the first pupil region on the photoelectric conversion unit PDB. With this configuration, a signal (an A image signal) based on charges generated by the photoelectric conversion unit PDA and a signal (a B image signal) based on charges generated by the photoelectric conversion unit PDB can be used as a phase difference detection signals for measuring a distance. In addition, a signal (the A image signal+the B image signal) based on the total charges generated by the photoelectric conversion unit PDA and the photoelectric conversion unit PDB can be used as a signal for generating an image.

As described above, according to the present embodiment, a phase difference can be detected based on signals output from the two circuit blocks of each pixel 12, and information on a distance to a subject can be acquired or the lens can be focused.

FIG. 13 is a view for explaining a positional relationship between elements constituting a pixel, and is a plan view in which dimension lines and the like are added to FIG. 12 while omitting reference signs and the like from FIG. 12. The direction in which pixels commonly wired by the control line 14 in FIG. 1 are arranged (the row direction or the horizontal direction) is illustrated as a first direction DIR1 in FIG. 13. In FIG. 13, as indicated by arrows in both the left and right directions, the “first direction DIR1” may refer to a left direction or a right direction. In addition, the direction in which pixels commonly wired by the vertical output line 16 in FIG. 1 are arranged (the column direction or the vertical direction) is illustrated as a second direction DIR2 in FIG. 13. Unlike the directions illustrated in FIG. 13, the direction in which pixels commonly wired by the control line 14 in FIG. 1 are arranged (the row direction or the horizontal direction) may be the second direction DIR2, and the direction in which pixels commonly wired by the vertical output line 16 in FIG. 1 are arranged (the column direction or the vertical direction) may be the first direction DIR1. In the following description, description will be given focusing on a pixel PIX1 surrounded by a dotted line, but since each pixel is arranged in a translationally symmetric manner, it can be said that the same applies to the other pixels.

The optical center of the photoelectric conversion region (the photoelectric conversion unit PDA+the photoelectric conversion unit PDB) of the pixel PIX1 is defined as an optical center 103. The centroid position of the charge holding unit MEM1A in plan view is defined as a centroid position MEM1A-G, and the centroid position of the charge holding unit MEM2A in plan view is defined as a centroid position MEM2A-G. The centroid position of the charge holding unit MEM1B in plan view is defined as a centroid position MEM1B-G, and the centroid position of the charge holding unit MEM2B in plan view is defined as a centroid position MEM2B-G.

Furthermore, the optical center of the photoelectric conversion region of the pixel (the second pixel) adjacent to the pixel PIX1 (the first pixel) in the first direction DIR1 (the left direction in FIG. 13) is defined as an optical center 110. The optical center of the photoelectric conversion region of the pixel (the third pixel) adjacent to the pixel PIX1 (the first pixel) in the first direction DIR1 (the right direction in FIG. 13) is defined as an optical center 111.

In the pixel PIX1, the charge holding unit MEM1A is disposed in the first direction DIR1 (the left direction in FIG. 13) with respect to the photoelectric conversion unit PDA. Here, the arrangement in the first direction DIR1 means that at least a part of the charge holding unit MEM1A and at least a part of the photoelectric conversion unit PDA are arranged adjacent to each other in the first direction DIR1. Alternatively, the arrangement in the first direction DIR1 means that any straight line parallel to the first direction DIR1 intersects both at least a part of the charge holding unit MEM1A and at least a part of the photoelectric conversion unit PDA. Furthermore, in the pixel PIX1, the charge holding unit MEM1B is disposed in the first direction DIR1 (the right direction in FIG. 13) with respect to the photoelectric conversion unit PDB.

In the present embodiment, when a distance between the optical center 103 and the centroid position MEM1A-G in plan view is defined as L1, and a distance between the optical center 103 and the centroid position MEM2A-G in plan view is defined as L2, L1<L2 is satisfied. In addition, when a distance between the optical center 103 and the centroid position MEM1B-G in plan view is defined as L1, and a distance between the optical center 103 and the centroid position MEM2B-G in plan view is defined as L2, L1<L2 is satisfied.

In addition, when a distance between the centroid position MEM1A-G and the optical center 110 of the adjacent pixel in plan view is defined as L3, and a distance between the centroid position MEM2A-G and the optical center 110 of the adjacent pixel in plan view is defined as L4, L3<L4 is satisfied. In addition, when a distance between the centroid position MEM1B-G and the optical center 111 of the adjacent pixel in plan view is defined as L3, and a distance between the centroid position MEM2B-G and the optical center 111 of the adjacent pixel is defined as L4, L3<L4 is satisfied.

As described above, the charge holding unit MEM1A and the charge holding unit MEM1B are used to hold signal charges generated during the N-th frame period by the photoelectric conversion unit only in the N-th frame. In addition, the charge holding unit MEM2A and the charge holding unit MEM2B are used to hold signal charges of the (N−1)-th frame until the signal charges acquired in the (N−1)-th frame, which is the previous frame, are transferred to the floating diffusion unit FD and read out through the amplification transistor M4 while the N-th frame is photographed.

For example, consider a case where stronger light is incident on the pixel PIX1 during the N-th frame period as compared with that during the (N−1)-th frame period. Some of the strong light incident on the photoelectric conversion unit PDA or the photoelectric conversion unit PDB of the pixel PIX1 may be diffracted in the semiconductor and leak out of the photoelectric conversion unit as stray light. If such stray light easily reaches the charge holding unit MEM2A or the charge holding unit MEM2B, photocharges are generated in the charge holding unit MEM2A or the charge holding unit MEM2B due to the stray light and superimposed on the signal charges of the previous frame held in the charge holding unit MEM2A or the charge holding unit MEM2B. That is, some of the photocharges of the current frame, which are not originally supposed to be added, are added to the signal charges acquired in the previous frame and held by the charge holding unit MEM2A or the charge holding unit MEM2B, resulting in a kind of crosstalk between frames.

Alternatively, when strong light is incident on the adjacent pixel adjacent to the pixel PIX1 in the first direction DIR1 during the N-th frame period, some of the strong light incident on the photoelectric conversion unit PDA or the photoelectric conversion unit PDB of the adjacent pixel may be diffracted in the semiconductor and leaked out of the photoelectric conversion unit as stray light. If such stray light easily reaches the charge holding unit MEM2A or the charge holding unit MEM2B of the pixel PIX1, photocharges may be generated in the charge holding unit MEM2A or the charge holding unit MEM2B due to the stray light. Then, some of the photocharges generated in the current frame period are added to the signal charges acquired in the previous frame and held by the charge holding unit MEM2A or the charge holding unit MEM2B, resulting in a kind of crosstalk between frames.

The stray light attenuates exponentially according to the traveling distance in the semiconductor, and according to the present embodiment, L1<L2 is satisfied. Therefore, the stray light leaking from the photoelectric conversion unit of the pixel PIX1 hardly reaches the charge holding unit MEM2A and the charge holding unit MEM2B. Furthermore, according to the present embodiment, since L3<L4 is satisfied, stray light leaking from the photoelectric conversion unit of the adjacent pixel adjacent in the first direction DIR1 hardly reaches the charge holding unit MEM2A and the charge holding unit MEM2B of the pixel PIX1.

Therefore, the photoelectric conversion apparatus according to the present embodiment is capable of acquiring a high-quality moving image because an image of an earlier frame is hardly affected by capturing an image of a later frame when a moving image is captured by a global shutter operation.

Note that, in the example of FIG. 12, the charge holding unit MEM1A and the charge holding unit MEM1B, and the charge holding unit MEM2A and the charge holding unit MEM2B are arranged symmetrically with respect to the optical center 103. In other words, the charge holding units are arranged to be line-symmetric with respect to a line passing through the optical center of the photoelectric conversion unit and orthogonal to the first direction. However, the arrangement of the elements is not limited thereto. For example, the elements may be arranged to be point-symmetric with respect to the optical center 103, as long as light leaking from the photoelectric conversion unit is distributed at a distance that hardly reaches the charge holding unit MEM2A and the charge holding unit MEM2B. As a result, it is easy to equalize the characteristics of the signals output from the photoelectric conversion unit PDA and the photoelectric conversion unit PDB.

### Third Embodiment

A photoelectric conversion apparatus according to a third embodiment will be described with reference to the drawings. The description of matters common to the first embodiment or the second embodiment will be simplified or omitted. A schematic configuration of the photoelectric conversion apparatus is similar to that in the first embodiment described with reference to FIG. 1. In the third embodiment, a circuit configuration of a pixel, and a driving method will be described, and then a configuration of a pixel unit formed on a semiconductor substrate will be described.

### Circuit Configuration of Pixel

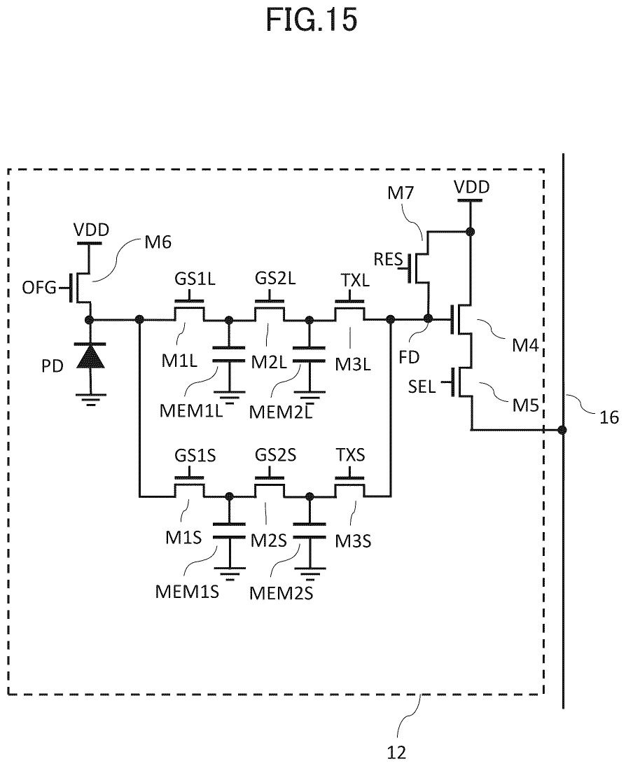

FIG. 15 is an equivalent circuit diagram illustrating a circuit configuration of a pixel 12 included in the photoelectric conversion apparatus according to the present embodiment. Each pixel 12 included in the photoelectric conversion apparatus according to the present embodiment includes two sets of circuit blocks each including three transfer transistors and two charge holding units. Further, each pixel 12 includes a photoelectric conversion unit PD and a charge discharge transistor M6 commonly connected to the input sides of the two sets of circuit blocks. Further, each pixel 12 includes a floating diffusion unit FD, a reset transistor M7, an amplification transistor M4, and a selection transistor M5 commonly connected to the output sides of the two sets of circuit blocks.

The first set of circuit blocks includes a transfer transistor MIL (a first transfer unit), a transfer transistor M2L (a second transfer unit), a transfer transistor M3L (a third transfer unit), a charge holding unit MEM1L (a first charge holding unit), and a charge holding unit MEM2L (a second charge holding unit). Furthermore, the second set of circuit blocks includes a transfer transistor MIS (a fourth transfer unit), a transfer transistor M2S (a fifth transfer unit), a transfer transistor M3S (a sixth transfer unit), a charge holding unit MEM1S (a third charge holding unit), and a charge holding unit MEM2S (a fourth charge holding unit).

The photoelectric conversion unit PD has an anode connected to a ground node and a cathode connected to a source of the transfer transistor MIL, a source of the transfer transistor MIS, and a source of the charge discharge transistor M6. A drain of the transfer transistor MIL is connected to a source of the transfer transistor M2L. A connection node between the drain of the transfer transistor MIL and the source of the transfer transistor M2L includes a capacitance component and functions as a charge holding unit (a charge holding unit MEM1L). A drain of the transfer transistor M2L is connected to a source of the transfer transistor M3L. A connection node between the drain of the transfer transistor M2L and the source of the transfer transistor M3L includes a capacitance component and functions as a charge holding unit (a charge holding unit MEM2L). A drain of the transfer transistor MIS is connected to a source of the transfer transistor M2S. A connection node between the drain of the transfer transistor MIS and the source of the transfer transistor M2S includes a capacitance component and functions as a charge holding unit (a charge holding unit MEM1S). A drain of the transfer transistor M2S is connected to a source of the transfer transistor M3S. A connection node between the drain of the transfer transistor M2S and the source of the transfer transistor M3S includes a capacitance component and functions as a charge holding unit (a charge holding unit MEM2S).

A drain of the transfer transistor M3L and a drain of the transfer transistor M3S are connected to a source of the reset transistor M7 and a gate of the amplification transistor M4. A connection node between the drain of the transfer transistor M3L, the drain of the transfer transistor M3S, the source of the reset transistor M7, and the gate of the amplification transistor M4 is a so-called floating diffusion unit FD. The floating diffusion unit FD includes a capacitance component (a floating diffusion capacitance) and functions as a charge holding unit.

A drain of the reset transistor M7, a drain of the amplification transistor M4, and a drain of the charge discharge transistor M6 are connected to a power supply voltage line (a voltage VDD). A source of the amplification transistor M4 is connected to a drain of the selection transistor M5. A source of the selection transistor M5 is connected to the vertical output line 16.

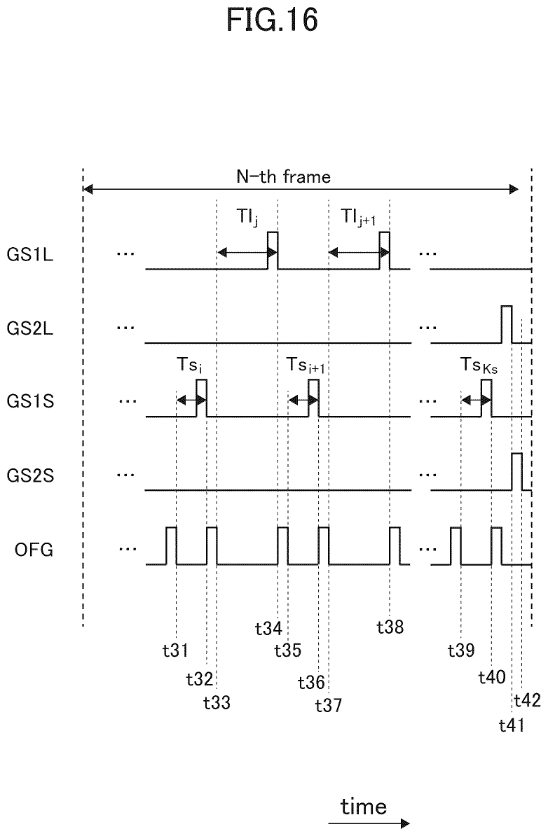

The control line 14 connected to each pixel from the vertical scanning circuit 20 (FIG. 1) includes a total of nine signal lines per pixel. A control signal GS1L illustrated in FIG. 16 is output from the vertical scanning circuit 20 to the signal line connected to the gate of the transfer transistor MIL. A control signal GS2L is output from the vertical scanning circuit 20 to the signal line connected to the gate of the transfer transistor M2L. A control signal TXL is output from the vertical scanning circuit 20 to the signal line connected to the gate of the transfer transistor M3L. A control signal GSIS illustrated in FIG. 16 is output from the vertical scanning circuit 20 to the signal line connected to the gate of the transfer transistor MIS. A control signal GS2S is output from the vertical scanning circuit 20 to the signal line connected to the gate of the transfer transistor M2S. A control signal TXS is output from the vertical scanning circuit 20 to the signal line connected to the gate of the transfer transistor M3S. A control signal RES is output from the vertical scanning circuit 20 to the signal line connected to the gate of the reset transistor M7. A control signal SEL is output from the vertical scanning circuit 20 to the signal line connected to the gate of the selection transistor M5. A control signal OFG illustrated in FIG. 16 is output from the vertical scanning circuit 20 to the signal line connected to the gate of the charge discharge transistor M6. In a case where each transistor is constituted by an N-type transistor, when a high-level control signal is supplied from the vertical scanning circuit 20, the corresponding transistor is turned on, and when a low-level control signal is supplied from the vertical scanning circuit 20, the corresponding transistor is turned off.

The photoelectric conversion unit PD converts (photoelectrically converts) incident light into charges in an amount corresponding to the amount of the incident light, and accumulates the generated charges. The transfer transistor MIL is turned on to function as a transfer unit that performs a transfer operation of transferring the charges held by the photoelectric conversion unit PD to the charge holding unit MEM1L. The transfer transistor M2L is turned on to function as a transfer unit that performs a transfer operation of transferring the charges held by the charge holding unit MEM1L to the charge holding unit MEM2L. The transfer transistor M3L is turned on to function as a transfer unit that performs a transfer operation of transferring the charges held by the charge holding unit MEM2L to the floating diffusion unit FD. The transfer transistor MIS is turned on to function as a transfer unit that performs a transfer operation of transferring the charges held by the photoelectric conversion unit PD to the charge holding unit MEM1S.

The transfer transistor M2S is turned on to function as a transfer unit that performs a transfer operation of transferring the charges held by the charge holding unit MEM1S to the charge holding unit MEM2S. The transfer transistor M3S is turned on to function as a transfer unit that performs a transfer operation of transferring the charges held by the charge holding unit MEM2S to the floating diffusion unit FD. The functions and operations of the reset transistor M7, the amplification transistor M4, the selection transistor M5, and the charge discharge transistor M6 are similar to those in the first embodiment.

### Method for Driving Photoelectric Conversion Apparatus

Next, a method for driving the photoelectric conversion apparatus according to the present embodiment will be described with reference to FIG. 16. FIG. 16 is a timing chart illustrating a drive related to an operation of reading out a signal of a pixel.

FIG. 16 illustrates a control signal GS1L supplied to the transfer transistor MIL, a control signal GSIS supplied to the transfer transistor MIS, a control signal GS2L supplied to the transfer transistor M2L, a control signal GS2S supplied to the transfer transistor M2S, and a control signal OFG supplied to the charge discharge transistor M6. When each control signal is at a high level, the corresponding transistor becomes active (a turn-on state). Note that, in the present embodiment, since the global shutter type drive is performed, the drive related to the operation of exposing the pixel unit 10 is simultaneously executed for the pixels 12 in all the rows. Furthermore, a pixel signal readout operation is sequentially executed for each row of pixels.

In the present embodiment, a plurality of (Ks) of accumulation periods Ts and a plurality of (Kl) of accumulation periods Tl are executed in each frame. The accumulation period Ts is a period for accumulating signal charges in the charge holding unit MEM1S, and the accumulation period Tl is a period for accumulating signal charges in the charge holding unit MEM1L. Hereinafter, operations in an i-th accumulation period Tsᵢ, an (i+1)-th accumulation period Tsᵢ₊₁, and a Ks-th accumulation period T_{sKs} among Ks accumulation periods Ts, and a j-th accumulation period Tlⱼ and a (j+1)-th accumulation period Tlⱼ₊₁ among Kl accumulation periods Tl will be described below. Here, i is an integer of 1 or more and Ks−2 or less. j is an integer of 1 or more and Kl−1 or less. Note that the numbers of times Ks and Kl can be appropriately set according to the total accumulation time or the like in one frame period, and the numbers of times Ks and Kl may be the same or different. The accumulation period Ts can be set to a time shorter than the accumulation period Tl.

It is assumed that the control signal OFG is at a high level immediately before time t31. The charge discharge transistor M6 is turned on when receiving a high-level control signal OFG, and the photoelectric conversion unit PD is reset to a potential corresponding to the voltage VDD.

At time t31, the vertical scanning circuit 20 controls the control signal OFG from the high level to the low level. As a result, the charge discharge transistor M6 is turned off, and the reset state of the photoelectric conversion unit PD is released. That is, the timing at which the control signal OFG transitions from the high level to the low level is a start time of the accumulation period Tsᵢ in the photoelectric conversion unit PD. Signal charges generated by incidence of photons onto the photoelectric conversion unit PD while the charge discharge transistor M6 is turned off are accumulated in the photoelectric conversion unit PD.

In a period from a predetermined timing after time t31 to time t32, the vertical scanning circuit 20 controls the control signal GSIS to the high level. As a result, the transfer transistor MIS is turned on, and the signal charges accumulated in the photoelectric conversion unit PD are transferred to the charge holding unit MEM1S. Time t32 when the transfer transistor MIS is turned off is an end time of the accumulation period Tsᵢ in the photoelectric conversion unit PD. That is, a period from time t31 to time t32 is a signal charge accumulation period Tsᵢ.

After time t32, the vertical scanning circuit 20 controls the control signal OFG from the low level to the high level. As a result, the charge discharge transistor M6 is turned on, and the photoelectric conversion unit PD is reset to a potential corresponding to the voltage VDD.

At subsequent time t33, the vertical scanning circuit 20 controls the control signal OFG from the high level to the low level. As a result, the charge discharge transistor M6 is turned off, and the reset state of the photoelectric conversion unit PD is released. That is, the timing at which the control signal OFG transitions from the high level to the low level is a start time of the accumulation period Tlⱼ in the photoelectric conversion unit PD. Signal charges generated by incidence of photons onto the photoelectric conversion unit PD while the charge discharge transistor M6 is turned off are accumulated in the photoelectric conversion unit PD.

In a period from a predetermined timing after time t33 to time t34, the vertical scanning circuit 20 controls the control signal GS1L to the high level. As a result, the transfer transistor MIL is turned on, and the signal charges accumulated in the photoelectric conversion unit PD are transferred to the charge holding unit MEM1L. Time t34 when the transfer transistor MIL is turned off is an end time of the accumulation period Tlⱼ in the photoelectric conversion unit PD. That is, a period from time t33 to time t34 is a signal charge accumulation period Tlⱼ.

Next, the accumulation period Ts and the accumulation period Tl are repeatedly performed a predetermined number of times in a procedure similar to that in the period from time t31 to time t34. For example, as illustrated in FIG. 16, an accumulation period Tsᵢ₊₁ is performed in a period from time t35 to time t36, an accumulation period Tlⱼ₊₁ is performed in a period from time t37 to time t38, and an accumulation period Ts_{Ks} is performed in a period from time t39 to time t40.

In this manner, Ks accumulation periods Ts and Kl accumulation periods Tl are executed in each frame. As a result, signal charges generated by the photoelectric conversion unit PD are held in the charge holding unit MEM1S during an accumulation period Tshort having a length obtained by adding the lengths of the Ks periods from the accumulation period Ts₁ to the accumulation period Ts_{Ks}. In addition, signal charges generated by the photoelectric conversion unit PD are held in the charge holding unit MEM1L during an accumulation period Tlong having a length obtained by adding the lengths of the Kl periods from the accumulation period Tl₁ to the accumulation period Tl_{Kl}.

The signal charges accumulated in the charge holding unit MEM1S can be transferred to the charge holding unit MEM2S after the readout of the pixel signal based on the signal charges of the (N−1)-th frame accumulated in the charge holding unit MEM2S is completed. In addition, the signal charges accumulated in the charge holding unit MEM1L can be transferred to the charge holding unit MEM2L after the readout of the pixel signal based on the signal charges of the (N−1)-th frame accumulated in the charge holding unit MEM2L is completed. Here, it is assumed that the readout of the pixel signal based on the signal charges of the (N−1)-th frame accumulated in the charge holding unit MEM2S and the charge holding unit MEM2L is completed by time t40.

Thereafter, in a period from a predetermined timing after time t40 to time t41, the vertical scanning circuit 20 controls the control signal GS2L to the high level. As a result, the transfer transistor M2L is turned on, and the signal charges accumulated in the charge holding unit MEM1L are transferred to the charge holding unit MEM2L.

In addition, in a period from a predetermined timing after time t40 to time t42, the vertical scanning circuit 20 controls the control signal GS2S to the high level. As a result, the transfer transistor M2S is turned on, and the signal charges accumulated in the charge holding unit MEM1S are transferred to the charge holding unit MEM2S.

Note that, here, the transfer of charges from the charge holding unit MEM1L to the charge holding unit MEM2L and the transfer of charges from the charge holding unit MEM1S to the charge holding unit MEM2S are performed at different timings, but may be performed simultaneously. When the transfer of charges from the charge holding unit MEM1L and the charge holding unit MEM1S to the charge holding unit MEM2L and the charge holding unit MEM2S is completed, the charge holding unit MEM1L and the charge holding unit MEM1S are empty. As a result, signal charges of the next frame (the (N+1)-th frame) can be accumulated in the charge holding unit MEM1L and the charge holding unit MEM1S. In this manner, according to the present embodiment, a high-quality moving image with a high dynamic range can be acquired.

### Configuration of Pixel Unit

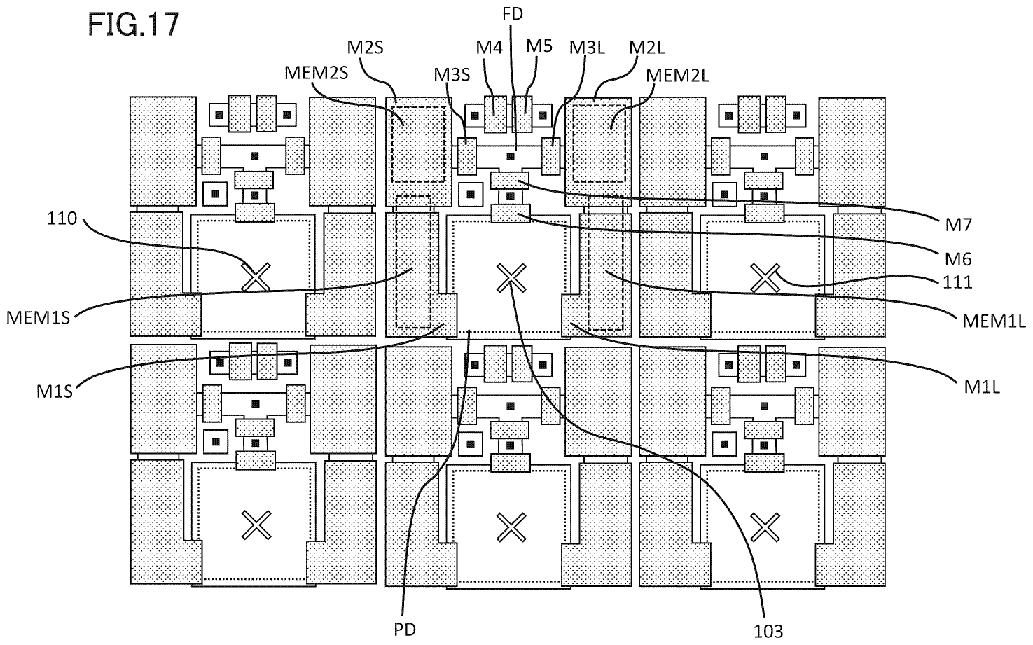

FIG. 17 is a plan view illustrating a configuration of the pixel unit formed on the semiconductor substrate in the photoelectric conversion apparatus according to the present embodiment. An active region and a gate electrode of a semiconductor, and a connection hole arranged in the active region are illustrated in a plan view from a direction orthogonal to the main surface of the semiconductor substrate. In FIG. 17, a portion of two rows and three columns is extracted from the pixel unit 10 in which a large number of pixels are arranged in a matrix. As illustrated, the pixel is arranged in a two-dimensional array with translational symmetry, and the pixels adjacent to each other have the same configurations and functions. Although FIG. 17 illustrates an example in which the pixels are arranged with one pixel being taken as a translationally symmetric unit, the pixels may be arranged with a plurality of pixels being taken as a translationally symmetric unit.

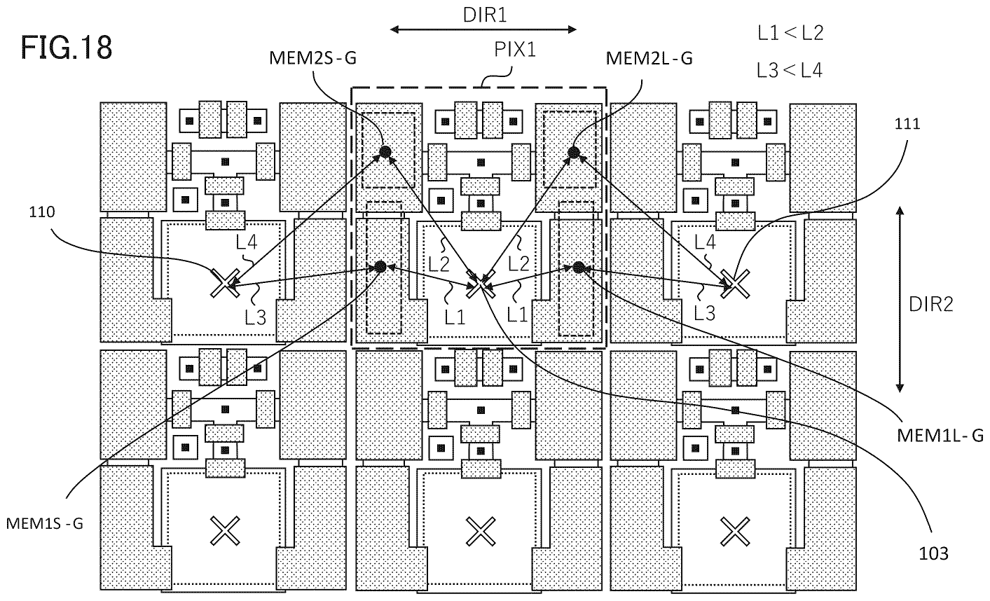

The arrangement relationship between the transfer transistor MIL (the first transfer unit), the transfer transistor M2L (the second transfer unit), the transfer transistor M3L (the third transfer unit), the charge holding unit MEM1L (the first charge holding unit), the charge holding unit MEM2L (the second charge holding unit), the transfer transistor MIS (the fourth transfer unit), the transfer transistor M2S (the fifth transfer unit), the transfer transistor M3S (the sixth transfer unit), the charge holding unit MEM1S (the third charge holding unit), and the charge holding unit MEM2S (the fourth charge holding unit) will be described with reference to FIG. 18.

FIG. 18 is a view for explaining a positional relationship between elements constituting a pixel, and is a plan view in which dimension lines and the like are added to FIG. 17 while omitting reference signs and the like from FIG. 17. The direction in which pixels commonly wired by the control line 14 in FIG. 1 are arranged (the row direction or the horizontal direction) is illustrated as a first direction DIR1 in FIG. 18. In FIG. 18, as indicated by arrows in both the left and right directions, the “first direction DIR1” may refer to a left direction or a right direction. In addition, the direction in which pixels commonly wired by the vertical output line 16 in FIG. 1 are arranged (the column direction or the vertical direction) is illustrated as a second direction DIR2 in FIG. 18. In the following description, description will be given focusing on a pixel PIX1 surrounded by a dotted line, but since each pixel is arranged in a translationally symmetric manner, it can be said that the same applies to the other pixels.

The optical center of the photoelectric conversion unit PD of the pixel PIX1 is defined as an optical center 103. The centroid position of the charge holding unit MEM1S in plan view is defined as a centroid position MEM1S-G, and the centroid position of the charge holding unit MEM2S in plan view is defined as a centroid position MEM2S-G. The centroid position of the charge holding unit MEM1L in plan view is defined as a centroid position MEM1L-G, and the centroid position of the charge holding unit MEM2L in plan view is defined as a centroid position MEM2L-G.

Furthermore, the optical center of the photoelectric conversion unit of the adjacent pixel (the second pixel) adjacent to the pixel PIX1 (the first pixel) in the first direction DIR1 (the left direction in FIG. 18) is defined as an optical center 110. The optical center of the photoelectric conversion unit of the adjacent pixel (the third pixel) adjacent to the pixel PIX1 (the first pixel) in the first direction DIR1 (the right direction in FIG. 18) is defined as an optical center 111.

In the pixel PIX1, the charge holding unit MEM1S is disposed in the first direction DIR1 (the left direction in FIG. 18) with respect to the photoelectric conversion unit PD. Here, the arrangement in the first direction DIR1 means that at least a part of the charge holding unit MEM1S and at least a part of the photoelectric conversion unit PD are arranged adjacent to each other in the first direction DIR1. Alternatively, the arrangement in the first direction DIR1 means that any straight line parallel to the first direction DIR1 intersects both at least a part of the charge holding unit MEM1S and at least a part of the photoelectric conversion unit PD. Furthermore, in the pixel PIX1, the charge holding unit MEM1L is disposed in the first direction DIR1 (the right direction in FIG. 18) with respect to the photoelectric conversion unit PD.

In the present embodiment, when a distance between the optical center 103 and the centroid position MEM1S-G in plan view is defined as L1, and a distance between the optical center 103 and the centroid position MEM2S-G in plan view is defined as L2, L1<L2 is satisfied. In addition, when a distance between the optical center 103 and the centroid position MEM1L-G in plan view is defined as L1, and a distance between the optical center 103 and the centroid position MEM2L-G in plan view is defined as L2, L1<L2 is satisfied.

In addition, when a distance between the centroid position MEM1S-G and the optical center 110 of the adjacent pixel in plan view is defined as L3, and a distance between the centroid position MEM2S-G and the optical center 110 of the adjacent pixel is defined as L4, L3<L4 is satisfied. In addition, when a distance between the centroid position MEM1L-G and the optical center 111 of the adjacent pixel in plan view is defined as L3, and a distance between the centroid position MEM2L-G and the optical center 111 of the adjacent pixel is defined as L4, L3<L4 is satisfied.

As described above, the charge holding unit MEM1S and the charge holding unit MEM1L are used to hold signal charges generated during the N-th frame period by the photoelectric conversion unit only in the N-th frame. In addition, the charge holding unit MEM2S and the charge holding unit MEM2L are used to hold signal charges of the (N−1)-th frame until the signal charges acquired in the (N−1)-th frame, which is the previous frame, are transferred to the floating diffusion unit FD and read out through the amplification transistor M4 while the N-th frame is photographed.

For example, consider a case where stronger light is incident on the pixel PIX1 during the N-th frame period as compared with that during the (N−1)-th frame period. Some of the strong light incident on the photoelectric conversion unit PD of the pixel PIX1 may be diffracted in the semiconductor and leak out of the photoelectric conversion unit PD as stray light. If such stray light easily reaches the charge holding unit MEM2S or the charge holding unit MEM2L, photocharges are generated in the charge holding unit MEM2S or the charge holding unit MEM2L due to the stray light and superimposed on the signal charges of the previous frame held in the charge holding unit MEM2S or the charge holding unit MEM2L. That is, some of the photocharges of the current frame, which are not originally supposed to be added, are added to the signal charges acquired in the previous frame and held by the charge holding unit MEM2S or the charge holding unit MEM2L, resulting in a kind of crosstalk between frames.

Alternatively, when strong light is incident on the adjacent pixel adjacent to the pixel PIX1 in the first direction DIR1 during the N-th frame period, some of the strong light incident on the photoelectric conversion unit PD of the adjacent pixel may be diffracted in the semiconductor and leaked out of the photoelectric conversion unit as stray light. If such stray light easily reaches the charge holding unit MEM2S or the charge holding unit MEM2L of the pixel PIX1, photocharges may be generated in the charge holding unit MEM2S or the charge holding unit MEM2L due to the stray light. Then, some of the photocharges generated in the current frame period are added to the signal charges acquired in the previous frame and held by the charge holding unit MEM2S or the charge holding unit MEM2L, resulting in a kind of crosstalk between frames.

The stray light attenuates exponentially according to the traveling distance in the semiconductor, and according to the present embodiment, L1<L2 is satisfied. Therefore, the stray light leaking from the photoelectric conversion unit PD of the pixel PIX1 hardly reaches the charge holding unit MEM2S and the charge holding unit MEM2L. Furthermore, according to the present embodiment, since L3<L4 is satisfied, stray light leaking from the photoelectric conversion unit of the adjacent pixel adjacent in the first direction DIR1 hardly reaches the charge holding unit MEM2S and the charge holding unit MEM2L of the pixel PIX1.

Therefore, the photoelectric conversion apparatus according to the present embodiment is capable of acquiring a high-quality moving image because an image of an earlier frame is hardly affected by capturing an image of a later frame when a moving image is captured by a global shutter operation.

Note that, in the example of FIG. 12, the charge holding unit MEM1A and the charge holding unit MEM1B, and the charge holding unit MEM2A and the charge holding unit MEM2B are arranged symmetrically with respect to the optical center 103. In other words, the charge holding units are arranged to be line-symmetric with respect to a line passing through the optical center of the photoelectric conversion unit and orthogonal to the first direction. However, the arrangement of the elements is not limited thereto. For example, the elements may be arranged to be point-symmetric with respect to the optical center 103, as long as light leaking from the photoelectric conversion unit is distributed at a distance that hardly reaches the charge holding unit MEM2. As a result, it is easy to equalize the characteristics of the signal at the time of long-second accumulation and the signal at the time of short-second accumulation.

### Fourth Embodiment

A photoelectric conversion apparatus according to a fourth embodiment will be described with reference to the drawings. The description of matters common to any of the embodiments described above will be simplified or omitted. A schematic configuration of the photoelectric conversion apparatus is similar to that in the first embodiment described with reference to FIG. 1. In the fourth embodiment, a circuit configuration of a pixel, and a driving method will be described, and then a configuration of a pixel unit formed on a semiconductor substrate will be described.

### Circuit Configuration of Pixel

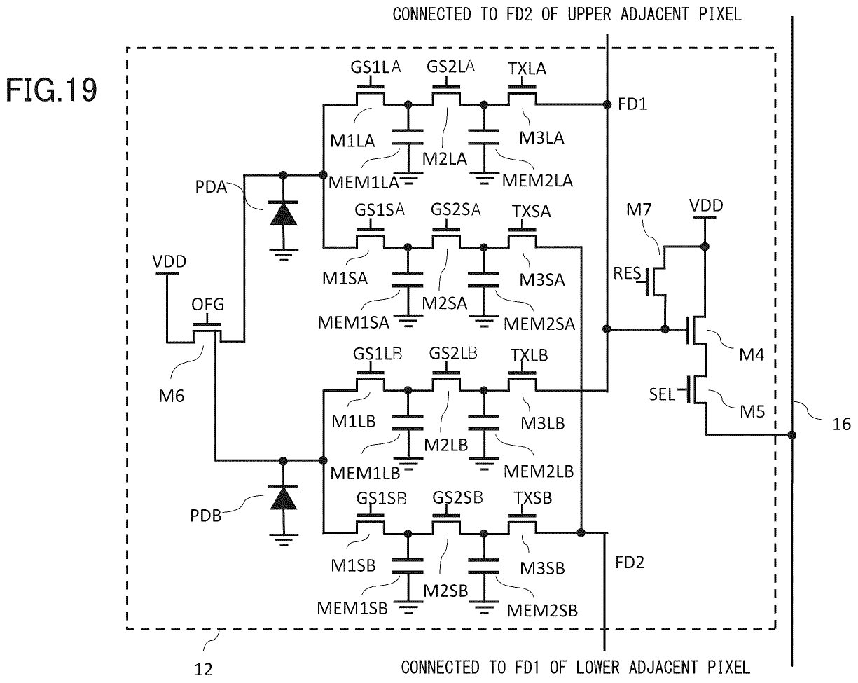

FIG. 19 is an equivalent circuit diagram illustrating a circuit configuration of a pixel 12 included in the photoelectric conversion apparatus according to the present embodiment. In the present embodiment, each pixel 12 includes a first circuit block and a second circuit block.

The first circuit block includes a photoelectric conversion unit PDA (a first photoelectric conversion unit), a transfer transistor M1LA (a first transfer unit), a transfer transistor M2LA (a second transfer unit), a transfer transistor M3LA (a third transfer unit), a transfer transistor MISA (a fourth transfer unit), a transfer transistor M2SA (a fifth transfer unit), a transfer transistor M3SA (a sixth transfer unit), a charge holding unit MEM1LA (a first charge holding unit), a charge holding unit MEM2LA (a second charge holding unit), a charge holding unit MEM1 SA (a third charge holding unit), and a charge holding unit MEM2SA (a fourth charge holding unit).

The second circuit block includes a photoelectric conversion unit PDB (a second photoelectric conversion unit), a transfer transistor MILB (a seventh transfer unit), a transfer transistor M2LB (an eighth transfer unit), a transfer transistor M3LB (a ninth transfer unit), a transfer transistor M1SB (a tenth transfer unit), a transfer transistor M2SB (an eleventh transfer unit), a transfer transistor M3SB (a twelfth transfer unit), a charge holding unit MEM1LB (a fifth charge holding unit), a charge holding unit MEM2LB (a sixth charge holding unit), a charge holding unit MEM1SB (a seventh charge holding unit), and a charge holding unit MEM2SB (an eighth charge holding unit).

The photoelectric conversion unit PDA has an anode connected to a ground node and a cathode connected to a source of the transfer transistor M1LA, a source of the transfer transistor MISA, and a source of the charge discharge transistor M6. A drain of the transfer transistor M1LA is connected to a source of the transfer transistor M2LA. A connection node between the drain of the transfer transistor M1LA and the source of the transfer transistor M2LA includes a capacitance component and functions as a charge holding unit (a charge holding unit MEM1LA). A drain of the transfer transistor M2LA is connected to a source of the transfer transistor M3LA. A connection node between the drain of the transfer transistor M2LA and the source of the transfer transistor M3LA includes a capacitance component and functions as a charge holding unit (a charge holding unit MEM2LA).

A drain of the transfer transistor MISA is connected to a source of the transfer transistor M2SA. A connection node between the drain of the transfer transistor MISA and the source of the transfer transistor M2SA includes a capacitance component and functions as a charge holding unit (a charge holding unit MEM1SA). A drain of the transfer transistor M2SA is connected to a source of the transfer transistor M3SA. A connection node between the drain of the transfer transistor M2SA and the source of the transfer transistor M3SA includes a capacitance component and functions as a charge holding unit (a charge holding unit MEM2SA).

The photoelectric conversion unit PDB has an anode connected to a ground node and a cathode connected to a source of the transfer transistor MILB, a source of the transfer transistor M1SB, and a source of the charge discharge transistor M6. A drain of the transfer transistor MILB is connected to a source of the transfer transistor M2LB. A connection node between the drain of the transfer transistor MILB and the source of the transfer transistor M2LB includes a capacitance component and functions as a charge holding unit (a charge holding unit MEM1LB). A drain of the transfer transistor M2LB is connected to a source of the transfer transistor M3LB. A connection node between the drain of the transfer transistor M2LB and the source of the transfer transistor M3LB includes a capacitance component and functions as a charge holding unit (a charge holding unit MEM2LB).

A drain of the transfer transistor M1SB is connected to a source of the transfer transistor M2SB. A connection node between the drain of the transfer transistor M1SB and the source of the transfer transistor M2SB includes a capacitance component and functions as a charge holding unit (a charge holding unit MEM1SB). A drain of the transfer transistor M2SB is connected to a source of the transfer transistor M3SB. A connection node between the drain of the transfer transistor M2SB and the source of the transfer transistor M3SB includes a capacitance component and functions as a charge holding unit (a charge holding unit MEM2SB).

A drain of the transfer transistor M3LA and a drain of the transfer transistor M3LB are connected to a source of the reset transistor M7 and a gate of the amplification transistor M4. A connection node of the drain of the transfer transistor M3LA, the drain of the transfer transistor M3LB, the source of the reset transistor M7, and the gate of the amplification transistor M4 is a floating diffusion unit FD1. The drain of the transfer transistor M3SA and the drain of the transfer transistor M3SB are connected to a source of a reset transistor M7 of the adjacent pixel on the upper side of the drawing and a gate of an amplification transistor M4 of the adjacent pixel on the upper side of the drawing. A connection node between the drain of the transfer transistor M3SA, the drain of the transfer transistor M3SB, the source of the reset transistor M7 of the adjacent pixel on the lower side of the drawing, and the gate of the amplification transistor M4 of the adjacent pixel on the upper side of the drawing is a floating diffusion unit FD2. The floating diffusion unit FD1 is connected to the floating diffusion unit FD2 of the adjacent pixel on the upper side of the drawing, and the floating diffusion unit FD2 is connected to the floating diffusion unit FD1 of the adjacent pixel on the lower side of the drawing. Each of the floating diffusion unit FD1 and the floating diffusion unit FD2 includes a capacitance component (a floating diffusion capacitance) and functions as a charge holding unit.

A drain of the reset transistor M7, a drain of the amplification transistor M4, and a drain of the charge discharge transistor M6 are connected to a power supply voltage line (a voltage VDD). A source of the amplification transistor M4 is connected to a drain of the selection transistor M5. A source of the selection transistor M5 is connected to the vertical output line 16.

Each control line 14 connected to each pixel from the vertical scanning circuit 20 (FIG. 1) includes a total of 15 signal lines. That is, the signal lines are connected to the gates of the 12 transfer transistors, the reset transistor M7, the selection transistor M5, and the charge discharge transistor M6 included in each pixel.

A control signal GS1LA is output from the vertical scanning circuit 20 to the signal line connected to the gate of the transfer transistor M1LA. A control signal GS2LA is output from the vertical scanning circuit 20 to the signal line connected to the gate of the transfer transistor M2LA. A control signal TXLA is output from the vertical scanning circuit 20 to the signal line connected to the gate of the transfer transistor M3LA. A control signal GS1SA is output from the vertical scanning circuit 20 to the signal line connected to the gate of the transfer transistor MISA. A control signal GS2SA is output from the vertical scanning circuit 20 to the signal line connected to the gate of the transfer transistor M2SA. A control signal TXSA is output from the vertical scanning circuit 20 to the signal line connected to the gate of the transfer transistor M3SA.

A control signal GS1LB is output from the vertical scanning circuit 20 to the signal line connected to the gate of the transfer transistor MILB. A control signal GS2LB is output from the vertical scanning circuit 20 to the signal line connected to the gate of the transfer transistor M2LB. A control signal TXLB is output from the vertical scanning circuit 20 to the signal line connected to the gate of the transfer transistor M3LB. A control signal GS1SB is output from the vertical scanning circuit 20 to the signal line connected to the gate of the transfer transistor M1SB. A control signal GS2SB is output from the vertical scanning circuit 20 to the signal line connected to the gate of the transfer transistor M2SB. A control signal TXSB is output from the vertical scanning circuit 20 to the signal line connected to the gate of the transfer transistor M3SB.

A control signal OFG is output from the vertical scanning circuit 20 to the signal line connected to the gate of the charge discharge transistor M6. A control signal SEL is output from the vertical scanning circuit 20 to the signal line connected to the gate of the selection transistor M5. A control signal RES is output from the vertical scanning circuit 20 to the signal line connected to the gate of the reset transistor M7.

Some of the corresponding transistors in the first circuit block and the second circuit block may be connected to a common signal line. In this case, each control line 14 may include 11 signal lines. That is, the same control signal may be supplied to the gate of the transfer transistor M1LA and the gate of the transfer transistor MILB via a common signal line. Similarly, the same control signal may be supplied to the gate of the transfer transistor MISA and the gate of the transfer transistor M1SB via a common signal line. The same control signal may be supplied to the gate of the transfer transistor M2LA and the gate of the transfer transistor M2LB via a common signal line.

The same control signal may be supplied to the gate of the transfer transistor M2SA and the gate of the transfer transistor M2SB via a common signal line. With this configuration, it is possible to ensure simultaneity of signals acquired from the two photoelectric conversion units PDA and PDB.

In addition, in a case where adjacent gates are driven in the same way, the gates may be integrated and the connection holes connecting the gates to the wiring may be grouped together.

The functions and operations of the first circuit block and the second circuit block described above are similar to those of the circuit blocks described in the second embodiment. In addition, the functions and operations of the reset transistor M7, the amplification transistor M4, the selection transistor M5, and the charge discharge transistor M6 are similar to those in the first embodiment.

According to the present embodiment, a high-quality moving image with a high dynamic range can be acquired. Furthermore, according to the present embodiment, a phase difference can be detected based on signals output from the two circuit blocks of each pixel 12, and information on a distance to a subject can be acquired or the lens can be focused.

In addition, in the present embodiment, the charge holding unit MEM2LA is connected to the charge holding unit MEM1LA via the transfer transistor M1LA, and the charge holding unit MEM2SA is connected to the charge holding unit MEM1SA via the transfer transistor MISA. That is, the pixel 12 includes the charge holding unit MEM2LA and the charge holding unit MEM2SA capable of holding charges, separately from the charge holding unit MEM1LA and the charge holding unit MEM1SA used to accumulate signal charges.

In addition, the charge holding unit MEM2LB is connected to the charge holding unit MEM1LB via the transfer transistor MILB, and the charge holding unit MEM2SB is connected to the charge holding unit MEM1SB via the transfer transistor M1SB. That is, the pixel 12 includes the charge holding unit MEM2LB and the charge holding unit MEM2SB capable of holding charges, separately from the charge holding unit MEM1LB and the charge holding unit MEM1SB used to accumulate signal charges. As a result, in the present embodiment, it is possible to perform an operation of accumulating signal charges of the next frame while holding signal charges of the previous frame. As a result, it is possible to read out signals even during a period in which signal charges are accumulated, thereby reducing a time region in which signal charges cannot be acquired in each frame period and acquiring a seamless moving image.

### Configuration of Pixel Unit

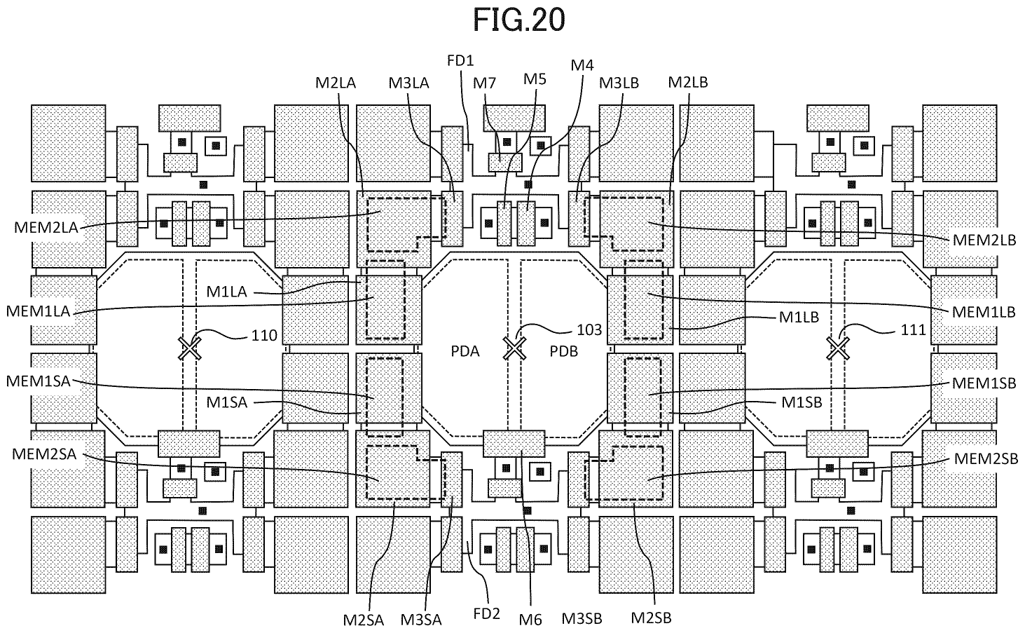

FIG. 20 is a plan view illustrating a configuration of the pixel unit formed on the semiconductor substrate in the photoelectric conversion apparatus according to the present embodiment. An active region of a semiconductor, a gate electrode, and a connection hole arranged in the active region are illustrated in a plan view from a direction orthogonal to the main surface of the semiconductor substrate. In FIG. 20, a portion of one row and three columns is extracted from the pixel unit 10 in which a large number of pixels are arranged in a matrix. As illustrated, the pixel is arranged in a two-dimensional array with translational symmetry, and the pixels adjacent to each other have the same configurations and functions. Although FIG. 20 illustrates an example in which the pixels are arranged with one pixel being taken as a translationally symmetric unit, the pixels may be arranged with a plurality of pixels being taken as a translationally symmetric unit.

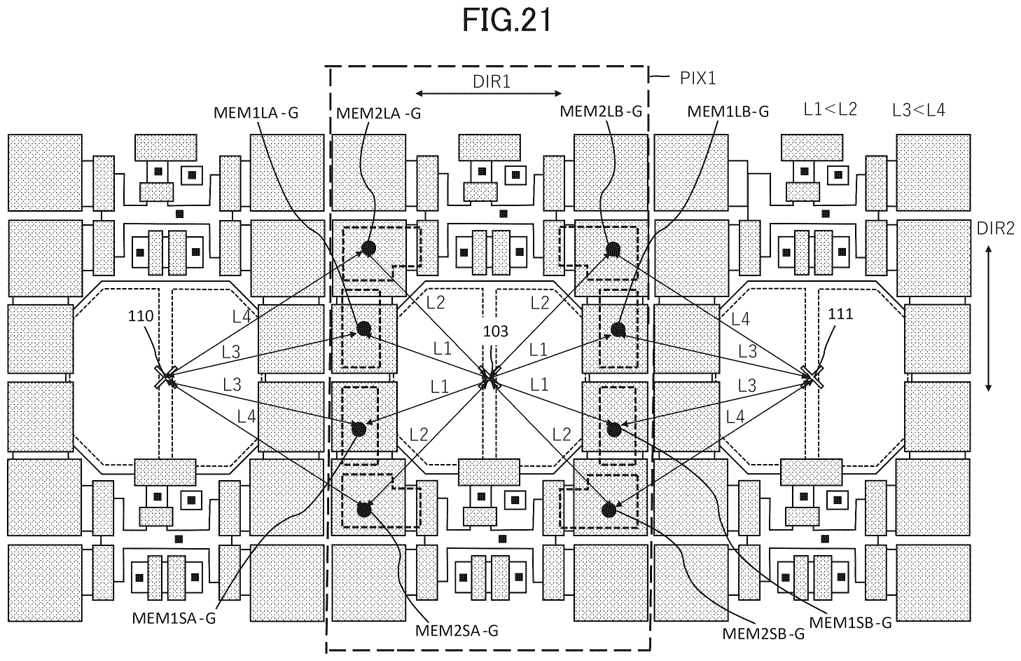

The arrangement relationship between the photoelectric conversion unit PDA (the first photoelectric conversion unit), the transfer transistor M1LA (the first transfer unit), the transfer transistor M2LA (the second transfer unit), the transfer transistor M3LA (the third transfer unit), the transfer transistor MISA (the fourth transfer unit), the transfer transistor M2SA (the fifth transfer unit), the transfer transistor M3SA (the sixth transfer unit), the charge holding unit MEM1LA (the first charge holding unit), the charge holding unit MEM2LA (the second charge holding unit), the charge holding unit MEM1SA (the third charge holding unit), the charge holding unit MEM2SA (the fourth charge holding unit), the photoelectric conversion unit PDB (the second photoelectric conversion unit), the transfer transistor MILB (the seventh transfer unit), the transfer transistor M2LB (the eighth transfer unit), the transfer transistor M3LB (the ninth transfer unit), the transfer transistor M1SB (the tenth transfer unit), the transfer transistor M2SB (the eleventh transfer unit), the transfer transistor M3SB (the twelfth transfer unit), the charge holding unit MEM1LB (the fifth charge holding unit), the charge holding unit MEM2LB (the sixth charge holding unit), the charge holding unit MEM1SB (the seventh charge holding unit), and the charge holding unit MEM2SB (the eighth charge holding unit) will be described with reference to FIG. 21.

FIG. 21 is a view for explaining a positional relationship between elements constituting a pixel, and is a plan view in which dimension lines and the like are added to FIG. 20 while omitting reference signs and the like from FIG. 20. The direction in which pixels commonly wired by the control line 14 in FIG. 1 are arranged (the row direction or the horizontal direction) is illustrated as a first direction DIR1 in FIG. 21. In FIG. 21, as indicated by arrows in both the left and right directions, the “first direction DIR1” may refer to a left direction or a right direction. In addition, the direction in which pixels commonly wired by the vertical output line 16 in FIG. 1 are arranged (the column direction or the vertical direction) is illustrated as a second direction DIR2 in FIG. 21. In the following description, description will be given focusing on a pixel illustrated at the center of the drawing, but since each pixel is arranged in a translationally symmetric manner, it can be said that the same applies to the other pixels.

The optical center of the photoelectric conversion region (the photoelectric conversion unit PDA+the photoelectric conversion unit PDB) of the pixel disposed at the center of the drawing is defined as an optical center 103. The centroid position of the charge holding unit MEM1LA in plan view is defined as a centroid position MEM1LA-G, and the centroid position of the charge holding unit MEM2LA in plan view is defined as a centroid position MEM2LA-G. The centroid position of the charge holding unit MEM1LB in plan view is defined as a centroid position MEM1LB-G, and the centroid position of the charge holding unit MEM2LB in plan view is defined as a centroid position MEM2LB-G. The centroid position of the charge holding unit MEM1SA in plan view is defined as a centroid position MEM1SA-G, and the centroid position of the charge holding unit MEM2SA in plan view is defined as a centroid position MEM2SA-G. The centroid position of the charge holding unit MEM1SB in plan view is defined as a centroid position MEM1SB-G, and the centroid position of the charge holding unit MEM2SB in plan view is defined as a centroid position MEM2SB-G.

Furthermore, the optical center of the photoelectric conversion region of the adjacent pixel (the second pixel) adjacent to the pixel of interest (the first pixel) in the first direction DIR1 (the left direction in FIG. 21) is defined as an optical center 110. The optical center of the photoelectric conversion region of the adjacent pixel (the third pixel) adjacent to the pixel of interest (the first pixel) in the first direction DIR1 (the right direction in FIG. 21) is defined as an optical center 111.

In the pixel of interest (pixel PIX1), the charge holding unit MEM1LA and the charge holding unit MEM1SA are disposed in the first direction DIR1 (the left direction in FIG. 21) with respect to the photoelectric conversion unit PDA. Here, the arrangement in the first direction DIR1 means that at least a part of the charge holding unit and at least a part of the photoelectric conversion unit are arranged adjacent to each other in the first direction DIR1. Alternatively, the arrangement in the first direction DIR1 means that any straight line parallel to the first direction DIR1 intersects both at least a part of the charge holding unit and at least a part of the photoelectric conversion unit. Furthermore, in the pixel of interest (pixel PIX1), the charge holding unit MEM1LB and the charge holding unit MEM1SB are disposed in the first direction DIR1 (the right direction in FIG. 21) with respect to the photoelectric conversion unit PDB.

In the present embodiment, when a distance between the optical center 103 and the centroid position MEM1LA-G of the pixel of interest (pixel PIX1) in plan view is defined as L1, and a distance between the optical center 103 and the centroid position MEM2LA-G in plan view is defined as L2, L1<L2 is satisfied. In addition, when a distance between the optical center 103 and the centroid position MEM1LB-G in plan view is defined as L1, and a distance between the optical center 103 and the centroid position MEM2LB-G in plan view is defined as L2, L1<L2 is satisfied. Further, when a distance between the optical center 103 and the centroid position MEM1SA-G in plan view is L1, and a distance between the optical center 103 and the centroid position MEM2SA-G is L2, L1<L2 is satisfied. In addition, when a distance between the optical center 103 and the centroid position MEM1SB-G in plan view is defined as L1, and a distance between the optical center 103 and the centroid position MEM2SB-G in plan view is defined as L2, L1<L2 is satisfied.

In addition, when a distance between the centroid position MEM1LA-G and the optical center 110 of the left adjacent pixel in plan view is defined as L3, and a distance between the centroid position MEM2LA-G and the optical center 110 of the left adjacent pixel in plan view is defined as L4, L3<L4 is satisfied. In addition, when a distance between the centroid position MEM1SA-G and the optical center 110 of the left adjacent pixel in plan view is defined as L3, and a distance between the centroid position MEM2SA-G and the optical center 110 of the left adjacent pixel in plan view is defined as L4, L3<L4 is satisfied.

In addition, when a distance between the centroid position MEM1LB-G and the optical center 111 of the right adjacent pixel in plan view is defined as L3, and a distance between the centroid position MEM2LB-G and the optical center 111 of the right adjacent pixel is defined as L4, L3<L4 is satisfied. In addition, when a distance between the centroid position MEM1SB-G and the optical center 111 of the right adjacent pixel in plan view is defined as L3, and a distance between the centroid position MEM2SB-G and the optical center 111 of the right adjacent pixel is defined as L4, L3<L4 is satisfied.

As described above, the charge holding unit MEM1LA, the charge holding unit MEM1LB, the charge holding unit MEM1SA, and the charge holding unit MEM1SB are used to hold signal charges generated during the N-th frame period by the photoelectric conversion unit only in the N-th frame. In addition, the charge holding unit MEM2LA, the charge holding unit MEM2LB, the charge holding unit MEM2SA, and the charge holding unit MEM2SB are used to hold signal charges of the (N−1)-th frame until the signal charges acquired in the (N−1)-th frame, which is the previous frame, are transferred to the floating diffusion unit and read out through the amplification transistor M4 while the N-th frame is photographed.

For example, consider a case where stronger light is incident on the pixel of interest (pixel PIX1) during the N-th frame period as compared with that during the (N−1)-th frame period. Some of the strong light incident on the photoelectric conversion unit PDA or the photoelectric conversion unit PDB of the pixel of interest (pixel PIX1) may be diffracted in the semiconductor and leak out of the photoelectric conversion unit as stray light. If such stray light easily reaches the charge holding unit MEM2LA, the charge holding unit MEM2LB, the charge holding unit MEM2SA, and the charge holding unit MEM2SB, photocharges are generated in these charge holding units due to the stray light and superimposed on the signal charges of the previous frame held in these charge holding units. That is, some of the photocharges of the current frame, which are not originally supposed to be added, are added to the signal charges acquired in the previous frame and held by these charge holding units, resulting in a kind of crosstalk between frames.

Alternatively, when strong light is incident on the adjacent pixel adjacent to the pixel of interest in the first direction DIR1 during the N-th frame period, some of the strong light incident on the photoelectric conversion unit PDA or the photoelectric conversion unit PDB of the adjacent pixel may be diffracted in the semiconductor and leaked out of the photoelectric conversion unit as stray light. If such stray light easily reaches the charge holding unit MEM2LA, the charge holding unit MEM2LB, the charge holding unit MEM2SA, and the charge holding unit MEM2SB of the pixel of interest, photocharges may be generated in these charge holding units due to the stray light. Then, some of the photocharges generated in the current frame period are added to the signal charges acquired in the previous frame and held by these charge holding units, resulting in a kind of crosstalk between frames.

The stray light attenuates exponentially according to the traveling distance in the semiconductor, and according to the present embodiment, L1<L2 is satisfied. Therefore, the stray light leaking from the photoelectric conversion unit of the pixel of interest hardly reaches these charge holding units. Furthermore, according to the present embodiment, since L3<L4 is satisfied, stray light leaking from the photoelectric conversion unit of the adjacent pixel adjacent in the first direction DIR1 hardly reaches these charge holding units of the pixel of interest.

Therefore, the photoelectric conversion apparatus according to the present embodiment is capable of acquiring a high-quality moving image because an image of an earlier frame is hardly affected by capturing an image of a later frame when a moving image is captured by a global shutter operation.

Note that, in the example of FIG. 20, the charge holding unit MEM1LA and the charge holding unit MEM1LB, the charge holding unit MEM2LA and the charge holding unit MEM2LB, the charge holding unit MEM1SA and the charge holding unit MEM1SB, and the charge holding unit MEM2SA and the charge holding unit MEM2SB are arranged symmetrically with respect to the optical center 103. In other words, the charge holding units are arranged to be line-symmetric with respect to a line passing through the optical center of the photoelectric conversion unit and orthogonal to the first direction. However, the arrangement of the elements is not limited thereto. For example, the elements may be arranged to be point-symmetric with respect to the optical center 103, as long as light leaking from the photoelectric conversion unit is distributed at a distance that hardly reaches the charge holding unit MEM2. As a result, it is easy to equalize the characteristics of the signal at the time of long-second accumulation and the signal at the time of short-second accumulation.

### Fifth Embodiment

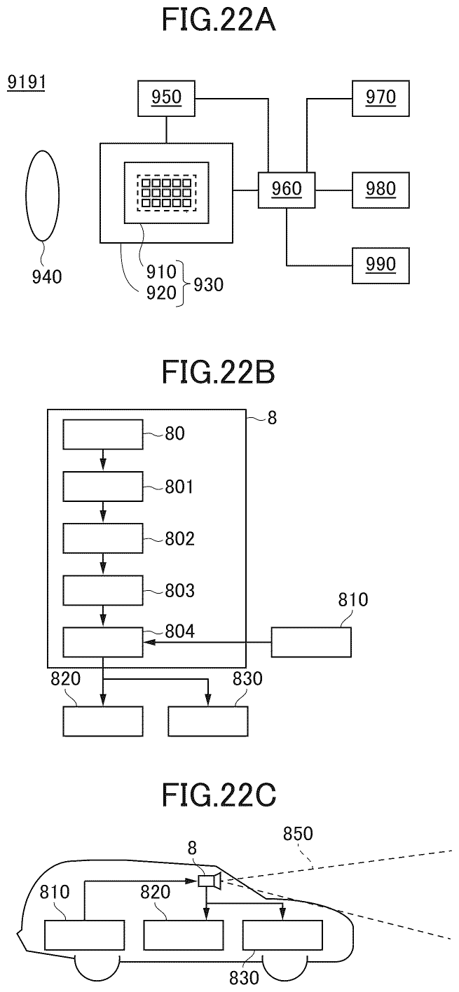

As a fifth embodiment, equipment including a semiconductor apparatus (a photoelectric conversion apparatus) according to any one of the above-described embodiments will be described. FIG. 22A is a schematic diagram for explaining equipment 9191 including a semiconductor apparatus 930 (a photoelectric conversion apparatus) according to the above-described embodiment. The equipment 9191 including the semiconductor apparatus 930 will be described in detail.

The semiconductor apparatus 930 includes a semiconductor device 910 in which a first chip serving as a photoelectric conversion apparatus and a second chip including at least one of a memory circuit and a logic circuit are integrated. In addition, the semiconductor apparatus 930 can include a package 920 that houses the semiconductor device 910, in addition to the semiconductor device 910. The package 920 can include a base to which semiconductor device 910 is fixed, and a lid such as glass facing the semiconductor device 910. The package 920 can further include a bonding member such as a bonding wire or a bump that connects a terminal provided on the base and a terminal provided on the semiconductor device 910.

The equipment 9191 can include at least one of an optical apparatus 940, a control apparatus 950, a processing apparatus 960, a display apparatus 970, a storage apparatus 980, and a mechanical apparatus 990. The optical apparatus 940 is, for example, a lens, a shutter, or a mirror provided to correspond to the semiconductor apparatus 930. The control apparatus 950 controls the semiconductor apparatus 930. The control apparatus 950 is, for example, a semiconductor apparatus such as an ASIC.

The processing apparatus 960 processes a signal output from the semiconductor apparatus 930. The processing apparatus 960 is a semiconductor apparatus such as a CPU or an ASIC for configuring an analog front end (AFE) or a digital front end (DFE). The display apparatus 970 is an EL display apparatus or a liquid crystal display apparatus that displays information (image) obtained by the semiconductor apparatus 930. The storage apparatus 980 is a magnetic device or a semiconductor device that stores information (image) obtained by the semiconductor apparatus 930. The storage apparatus 980 is a volatile memory such as an SRAM or a DRAM, or a nonvolatile memory such as a flash memory or a hard disk drive.

The mechanical apparatus 990 includes an operation unit or a propulsion unit such as a motor or an engine. In the equipment 9191, a signal output from the semiconductor apparatus 930 is displayed on the display apparatus 970, or is transmitted to the outside by a communication apparatus (not illustrated) included in the equipment 9191. Therefore, the equipment 9191 preferably further includes a storage apparatus 980 and a processing apparatus 960 separately from a storage circuit and an arithmetic circuit of the semiconductor apparatus 930. The mechanical apparatus 990 may be controlled based on a signal output from the semiconductor apparatus 930.

Furthermore, the equipment 9191 is suitable for electronic equipment such as an information terminal having a photographing function (e.g., a smartphone or a wearable terminal) or a camera (e.g., a lens-interchangeable camera, a compact camera, a video camera, or a surveillance camera). The mechanical apparatus 990 in the camera can drive the components of the optical apparatus 940 for zooming, focusing, and shutter operations. Alternatively, the mechanical apparatus 990 in the camera can move the semiconductor apparatus 930 for a vibration-proof operation.

Furthermore, the equipment 9191 may be transport equipment such as a vehicle, a ship, or a flying object. The mechanical apparatus 990 in the transport equipment can be used as a moving apparatus. The equipment 9191 serving as transport equipment is suitable for transporting the semiconductor apparatus 930 and assisting and/or automating driving (steering) by a photographing function. The processing apparatus 960 for assisting and/or automating driving (steering) can perform processing for operating the mechanical apparatus 990 serving as a moving apparatus based on information obtained by the semiconductor apparatus 930. Alternatively, the equipment 9191 may be medical equipment such as an endoscope, measuring equipment such as a distance measuring sensor, analyzing equipment such as an electron microscope, an office equipment such as a copying machine, or industrial equipment such as a robot. According to the above-described embodiment, it is possible to stably acquire an image having good characteristics.

Therefore, when the semiconductor apparatus 930 according to the present embodiment is used in the equipment 9191, the value of the equipment can also be improved. For example, it is possible to obtain excellent performance when the semiconductor apparatus 930 is mounted on transport equipment to photograph the outside of the transport equipment or measure the external environment. Therefore, in manufacturing and selling transport equipment, it is advantageous to determine to mount the semiconductor apparatus according to the present embodiment on the transport equipment in order to enhance the performance of the transport equipment itself. In particular, the semiconductor apparatus 930 is suitable for transport equipment that performs driving assistance and/or automatic driving of the transport equipment using information obtained by the semiconductor apparatus. Note that the implementation in a vehicle, a ship, a flying object, and the like is not limited to application to equipment practically used for transportation purposes, and is suitable for, for example, a drone or the like that takes aerial photographs for various purposes, including inspecting buildings and agricultural facilities, and monitoring natural phenomena.

A photoelectric conversion system and a moving object according to the present embodiment will be described with reference to FIGS. 22B and 22C. FIG. 22B illustrates an example of a photoelectric conversion system related to an in-vehicle camera. A photoelectric conversion system 8 includes a photoelectric conversion apparatus 80. The photoelectric conversion apparatus 80 is the photoelectric conversion apparatus serving as an electronic component described in the above embodiment. The photoelectric conversion system 8 includes an image processing unit 801 that performs image processing on data on plurality of images acquired by the photoelectric conversion apparatus 80, and a parallax acquisition unit 802 that calculates a parallax (a phase difference between parallax images) from the data on the plurality of images acquired by the photoelectric conversion system 8. Furthermore, the photoelectric conversion system 8 includes a distance acquisition unit 803 that calculates a distance to an object based on the calculated parallax, and a collision determination unit 804 that determines whether there is a possibility of collision based on the calculated distance. Here, the parallax acquisition unit 802 or the distance acquisition unit 803 are an example of a distance information acquisition unit that acquires information on a distance to an object. That is, the distance information is information regarding parallax, a defocus amount, a distance to an object, etc. The collision determination unit 804 may determine a possibility of collision using any one of these types of distance information. The distance information acquisition unit may be realized by dedicated hardware, or may be realized by a software module. In addition, the distance information acquisition unit may be realized by a field programmable gate array (FPGA), an application specific integrated circuit (ASIC), or the like.

The photoelectric conversion system 8 is connected to a vehicle information acquisition apparatus 810, and can acquire vehicle information such as a vehicle speed, a yaw rate, and a steering angle. In addition, the photoelectric conversion system 8 is connected to a control ECU 820, which is a control apparatus that outputs a control signal for generating a braking force on the vehicle based on a determination result of the collision determination unit 804. In addition, the photoelectric conversion system 8 is also connected to an alarm device 830 that issues an alarm to a driver based on a determination result of the collision determination unit 804. For example, in a case where the possibility of collision is high as a determination result of the collision determination unit 804, the control ECU 820 performs vehicle control to avoid collision and reduce damage by applying a brake, returning an accelerator, suppressing engine output, or the like. The alarm device 830 warns a user by sounding an alarm, displaying alarm information on a screen of a car navigation system or the like, applying vibrations to a seat belt or a steering wheel, or the like.

In the present embodiment, the periphery of the vehicle, for example, the front or the rear, is imaged by the photoelectric conversion system 8.

FIG. 22C illustrates a photoelectric conversion system when capturing an image of an area ahead of the vehicle (an imaging range 850). The vehicle information acquisition apparatus 810 sends an instruction to the photoelectric conversion system 8 or the photoelectric conversion apparatus 80. With such a configuration, the distance measurement accuracy can be further improved.

Although it has been described above as an example that the control is performed not to collide with another vehicle, the control can also be performed for automatic driving to follow another vehicle, or for automatic driving to avoid straying from lanes. Furthermore, the photoelectric conversion system can be applied to, for example, a moving object (a moving apparatus) such as a ship, an aircraft, or an industrial robot, not limited to a vehicle such as a host vehicle. In addition, the photoelectric conversion system can also be applied equipment that widely use object recognition, such as an intelligent transport system (ITS), not limited to a moving object.

The photoelectric conversion apparatus according to the above-described embodiment is capable of stably acquiring an image having good characteristics because an image of an earlier frame is hardly affected while an image of a later frame is being captured when a moving image is captured by a global shutter operation.

The equipment according to the present embodiment can include at least one of an optical apparatus corresponding to the semiconductor apparatus according to any one of the above-described embodiments, a control apparatus that controls the semiconductor apparatus according to any one of the above-described embodiments, and a processing apparatus that processes information obtained from the semiconductor apparatus according to any one of the above-described embodiments. Alternatively, the equipment according to the present embodiment can include at least one of a display apparatus that displays information obtained from the semiconductor apparatus according to any one of the above-described embodiments, a storage apparatus that stores information obtained from the semiconductor apparatus according to any one of the above-described embodiments, and a mechanical apparatus that operates based on information obtained from the semiconductor apparatus according to any one of the above-described embodiments.

### OTHER EMBODIMENTS

Note that the present invention is not limited to the embodiments described above, and many modifications can be made within the technical spirit of the present invention. For example, all or some of the different embodiments and examples described above may be combined for implementation.

The application of the photoelectric conversion apparatus described in each of the embodiments is not limited to the imaging use. For example, the photoelectric conversion apparatus described in each of the embodiments is also applicable to a distance measuring apparatus (an apparatus for detecting a focus, measuring a distance using a time of flight (TOF), or the like), a photometric device (a device for measuring the amount of incident light or the like), or the like.

The photoelectric conversion apparatus to which the present invention can be applied is not limited to a specific form, and may be, for example, either a front side-irradiated type sensor or a back-illuminated sensor. Alternatively, the photoelectric conversion apparatus to which the present invention can be applied may be a stacked-type photoelectric conversion apparatus in which a semiconductor chip including a light receiving unit and a semiconductor chip including an electric circuit such as a logic circuit are stacked.

The present invention can also be realized by processing in which a program for implementing one or more functions of the embodiments is supplied to a system or an apparatus via a network or a storage medium, and one or more processors in a computer of the system or the apparatus read and execute the program. Also, the present invention can be realized by a circuit (e.g., an ASIC) that implements one or more functions.

According to the present invention, it is possible to provide a photoelectric conversion apparatus in which an image of an earlier frame is hardly affected by capturing an image of a later frame when a moving image is captured by a global shutter operation.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-069318, filed Apr. 22, 2024, which is hereby incorporated by reference herein in its entirety.

What is claimed is:

1. A photoelectric conversion apparatus of a global shutter type comprising
a plurality of pixels arranged two-dimensionally on a semiconductor substrate and configured to perform photoelectric conversion operations in a same period, wherein
each of the plurality of pixels includes a photoelectric conversion unit, a first transfer unit, a first charge holding unit, a second transfer unit, a second charge holding unit, a third transfer unit, and a signal output unit,
in each of the plurality of pixels, charges generated by the photoelectric conversion unit are transferred to the first charge holding unit by the first transfer unit, the charges held in the first charge holding unit are transferred to the second charge holding unit by the second transfer unit, and the charges held in the second charge holding unit are transferred to the signal output unit by the third transfer unit,
the plurality of pixels includes a first pixel and a second pixel adjacent to each other in a first direction,
in the first pixel, the first charge holding unit is disposed in the first direction with respect to the photoelectric conversion unit,
in the first pixel, the photoelectric conversion unit, the first charge holding unit, and the second charge holding unit are arranged to satisfy L1<L2, where L1 denotes a distance from an optical center of the photoelectric conversion unit to a centroid of the first charge holding unit, and L2 denotes a distance from the optical center of the photoelectric conversion unit to a centroid of the second charge holding unit, and
the photoelectric conversion unit of the second pixel, the first charge holding unit of the first pixel, and the second charge holding unit of the first pixel are arranged to satisfy L3<L4, where L3 denotes a distance from an optical center of the photoelectric conversion unit of the second pixel to the centroid of the first charge holding unit of the first pixel, and L4 denotes a distance from the optical center of the photoelectric conversion unit of the second pixel to the centroid of the second charge holding unit of the first pixel.

2. The photoelectric conversion apparatus according to claim 1, wherein
the photoelectric conversion unit included in each of the plurality of pixels includes a first photoelectric conversion unit and a second photoelectric conversion unit arranged in the first direction,
each of the plurality of pixels further includes a fourth transfer unit, a third charge holding unit, a fifth transfer unit, a fourth charge holding unit, and a sixth transfer unit,
the plurality of pixels includes a third pixel disposed adjacent to the first pixel and opposite to the second pixel in the first direction,
in each of the plurality of pixels, charges generated by the first photoelectric conversion unit are transferred to the first charge holding unit by the first transfer unit, the charges held in the first charge holding unit are transferred to the second charge holding unit by the second transfer unit, and the charges held in the second charge holding unit are transferred to the signal output unit by the third transfer unit,
in each of the plurality of pixels, charges generated by the second photoelectric conversion unit are transferred to the third charge holding unit by the fourth transfer unit, the charges held in the third charge holding unit are transferred to the fourth charge holding unit by the fifth transfer unit, and the charges held in the fourth charge holding unit are transferred to the signal output unit by the sixth transfer unit,
in the first pixel, the first charge holding unit is disposed in the first direction with respect to the photoelectric conversion unit, and the photoelectric conversion unit, the first charge holding unit, and the second charge holding unit of the first pixel are arranged to satisfy L1<L2, where L1 denotes a distance from a first optical center that is the optical center of the photoelectric conversion unit to the centroid of the first charge holding unit, and L2 denotes a distance from the first optical center to the centroid of the second charge holding unit,
in the first pixel, the third charge holding unit is disposed in the first direction with respect to the photoelectric conversion unit, and the photoelectric conversion unit, the third charge holding unit, and the fourth charge holding unit of the first pixel are arranged to satisfy L1<L2, where L1 denotes a distance from the first optical center to a centroid of the third charge holding unit, and L2 denotes a distance from the first optical center to a centroid of the fourth charge holding unit,
the photoelectric conversion unit of the second pixel, the first charge holding unit of the first pixel, and the second charge holding unit of the first pixel are arranged to satisfy L3<L4, where L3 denotes a distance from a second optical center that is the optical center of the photoelectric conversion unit of the second pixel to the centroid of the first charge holding unit of the first pixel, and L4 denotes a distance from the second optical center to the centroid of the second charge holding unit of the first pixel, and
the photoelectric conversion unit of the third pixel, the third charge holding unit of the first pixel, and the fourth charge holding unit of the first pixel are arranged to satisfy L3<L4, where L3 denotes a distance from a third optical center that is an optical center of the photoelectric conversion unit of the third pixel to the centroid of the third charge holding unit of the first pixel, and L4 denotes a distance from the third optical center to the centroid of the fourth charge holding unit of the first pixel.

3. The photoelectric conversion apparatus according to claim 2, wherein
in each of the plurality of pixels, the first charge holding unit and the third charge holding unit are arranged to be line-symmetric with respect to a line passing through the optical center of the photoelectric conversion unit and orthogonal to the first direction, or are arranged to be point-symmetric with respect to the optical center, and
in each of the plurality of pixels, the second charge holding unit and the fourth charge holding unit are arranged to be line-symmetric with respect to the line, or are arranged to be point-symmetric with respect to the optical center.

4. The photoelectric conversion apparatus according to claim 2, wherein
each of the plurality of pixels includes a microlens shared by the first photoelectric conversion unit and the second photoelectric conversion unit.

5. The photoelectric conversion apparatus according to claim 1, wherein
each of the plurality of pixels further includes a fourth transfer unit, a third charge holding unit, a fifth transfer unit, a fourth charge holding unit, and a sixth transfer unit,
the plurality of pixels includes a third pixel disposed adjacent to the first pixel and opposite to the second pixel in the first direction, and
in each of the plurality of pixels, charges generated by the photoelectric conversion unit are transferred to the first charge holding unit by the first transfer unit, and the charges held in the first charge holding unit are transferred to the second charge holding unit by the second transfer unit, the charges held in the second charge holding unit are transferred to the signal output unit by the third transfer unit, or the charges generated by the photoelectric conversion unit transferred to the third charge holding unit by the fourth transfer unit, the charges held in the third charge holding unit are transferred to the fourth charge holding unit by the fifth transfer unit, and the charges held in the fourth charge holding unit are transferred to the signal output unit by the sixth transfer unit,
in the first pixel, the third charge holding unit is disposed in the first direction with respect to the photoelectric conversion unit, and the photoelectric conversion unit, the third charge holding unit, and the fourth charge holding unit of the first pixel are arranged to satisfy L1<L2, where L1 denotes a distance from the optical center of the photoelectric conversion unit to a centroid of the third charge holding unit, and L2 denotes a distance from the optical center of the photoelectric conversion unit to a centroid of the fourth charge holding unit, and
the photoelectric conversion unit of the third pixel, the third charge holding unit of the first pixel, and the fourth charge holding unit of the first pixel are arranged to satisfy L3<L4, where L3 is a distance from an optical center of the photoelectric conversion unit of the third pixel to the centroid of the third charge holding unit of the first pixel, and L4 is a distance from the optical center of the photoelectric conversion unit of the third pixel to the centroid of the fourth charge holding unit of the first pixel.

6. The photoelectric conversion apparatus according to claim 5, wherein
in each of the plurality of pixels, the first charge holding unit and the third charge holding unit are arranged to be line-symmetric with respect to a line passing through the optical center of the photoelectric conversion unit and orthogonal to the first direction, or are arranged to be point-symmetric with respect to the optical center, and
in each of the plurality of pixels, the second charge holding unit and the fourth charge holding unit are arranged to be line-symmetric with respect to the line, or are arranged to be point-symmetric with respect to the optical center.

7. The photoelectric conversion apparatus according to claim 1, wherein
the photoelectric conversion unit included in each of the plurality of pixels includes a first photoelectric conversion unit and a second photoelectric conversion unit arranged in the first direction,
each of the plurality of pixels further includes a fourth transfer unit, a third charge holding unit, a fifth transfer unit, a fourth charge holding unit, a sixth transfer unit, a seventh transfer unit, a fifth charge holding unit, an eighth transfer unit, a sixth charge holding unit, a ninth transfer unit, a tenth transfer unit, a seventh charge holding unit, an eleventh transfer unit, an eighth charge holding unit, and a twelfth transfer unit,
the plurality of pixels includes a third pixel disposed adjacent to the first pixel and opposite to the second pixel in the first direction,
in each of the plurality of pixels, charges generated by the first photoelectric conversion unit are transferred to the first charge holding unit by the first transfer unit, the charges held in the first charge holding unit are transferred to the second charge holding unit by the second transfer unit, and the charges held in the second charge holding unit are transferred to the signal output unit by the third transfer unit, or the charges generated by the first photoelectric conversion unit are transferred to the third charge holding unit by the fourth transfer unit, and the charges held in the third charge holding unit are transferred to the fourth charge holding unit by the fifth transfer unit, and the charges held in the fourth charge holding unit are transferred to the signal output unit by the sixth transfer unit,
in each of the plurality of pixels, charges generated by the second photoelectric conversion unit are transferred to the fifth charge holding unit by the seventh transfer unit, the charges held in the fifth charge holding unit are transferred to the sixth charge holding unit by the eighth transfer unit, and the charges held in the sixth charge holding unit are transferred to a second signal output unit different from the signal output unit by the ninth transfer unit, or the charges generated by the second photoelectric conversion unit are transferred to the seventh charge holding unit by the tenth transfer unit, and the charges held in the seventh charge holding unit are transferred to the eighth charge holding unit by the eleventh transfer unit, and, the charges held in the eighth charge holding unit are transferred to the second signal output unit by the twelfth transfer unit,
in the first pixel, the third charge holding unit is disposed in the first direction with respect to the photoelectric conversion unit, and the photoelectric conversion unit, the third charge holding unit, and the fourth charge holding unit of the first pixel are arranged to satisfy L1<L2, where L1 denotes a distance from the optical center of the photoelectric conversion unit to a centroid of the third charge holding unit, and L2 denotes a distance from the optical center of the photoelectric conversion unit to a centroid of the fourth charge holding unit,
the photoelectric conversion unit of the second pixel, the third charge holding unit of the first pixel, and the fourth charge holding unit of the first pixel are arranged to satisfy L3<L4, where L3 denotes a distance from the optical center of the photoelectric conversion unit of the second pixel to the centroid of the third charge holding unit of the first pixel, and L4 is a distance from the optical center of the photoelectric conversion unit of the second pixel to the centroid of the fourth charge holding unit of the first pixel,
in the first pixel, the fifth charge holding unit is disposed in the first direction with respect to the photoelectric conversion unit, and the photoelectric conversion unit, the fifth charge holding unit, and the sixth charge holding unit of the first pixel are arranged to satisfy L1<L2, where L1 denotes a distance from the optical center of the photoelectric conversion unit to a centroid of the fifth charge holding unit, and L2 denotes a distance from the optical center of the photoelectric conversion unit to a centroid of the sixth charge holding unit,
the photoelectric conversion unit of the third pixel, the fifth charge holding unit of the first pixel, and the sixth charge holding unit of the first pixel are arranged to satisfy L3<L4, where L3 denotes a distance from an optical center of the photoelectric conversion unit of the third pixel to the centroid of the fifth charge holding unit of the first pixel, and L4 denotes a distance from the optical center of the photoelectric conversion unit of the third pixel to the centroid of the sixth charge holding unit of the first pixel,
in the first pixel, the seventh charge holding unit is disposed in the first direction with respect to the photoelectric conversion unit, and the photoelectric conversion unit, the seventh charge holding unit, and the eighth charge holding unit of the first pixel are arranged to satisfy L1<L2, where L1 denotes a distance from the optical center of the photoelectric conversion unit to a centroid of the seventh charge holding unit, and L2 denotes a distance from the optical center of the photoelectric conversion unit to a centroid of the eighth charge holding unit, and
the photoelectric conversion unit of the third pixel, the seventh charge holding unit of the first pixel, and the eighth charge holding unit of the first pixel are arranged to satisfy L3<L4, where L3 denotes a distance from the optical center of the photoelectric conversion unit of the third pixel to the centroid of the seventh charge holding unit of the first pixel, and L4 denotes a distance from the optical center of the photoelectric conversion unit of the third pixel to the centroid of the eighth charge holding unit of the first pixel.

8. The photoelectric conversion apparatus according to claim 7, wherein
in each of the plurality of pixels, the first charge holding unit and the fifth charge holding unit are arranged to be line-symmetric with respect to a line passing through the optical center of the photoelectric conversion unit and orthogonal to the first direction, or are arranged to be point-symmetric with respect to the optical center,
in each of the plurality of pixels, the second charge holding unit and the sixth charge holding unit are arranged to be line-symmetric with respect to the line, or are arranged to be point-symmetric with respect to the optical center,
in each of the plurality of pixels, the third charge holding unit and the seventh charge holding unit are arranged to be line-symmetric with respect to the line, or are arranged to be point-symmetric with respect to the optical center, and
in each of the plurality of pixels, the fourth charge holding unit and the eighth charge holding unit are arranged to be line-symmetric with respect to the line, or are arranged to be point-symmetric with respect to the optical center.

9. The photoelectric conversion apparatus according to claim 7, wherein
each of the plurality of pixels includes a microlens shared by the first photoelectric conversion unit and the second photoelectric conversion unit.

10. The photoelectric conversion apparatus according to claim 1, wherein
in a case where an image of one frame is captured,
signal charges generated by the photoelectric conversion unit in a current frame are transferred to the first charge holding unit via the first transfer unit, signal charges of a one-previous frame held in the second charge holding unit are transferred to the signal output unit via the third transfer unit, and then the signal charges of the current frame held in the first charge holding unit are transferred to the second charge holding unit via the second transfer unit.

11. The photoelectric conversion apparatus according to claim 2, wherein
in a case where an image of one frame is captured,
signal charges generated by the first photoelectric conversion unit in a current frame are transferred to the first charge holding unit via the first transfer unit, signal charges of a one-previous frame held in the second charge holding unit are transferred to the signal output unit via the third transfer unit, and then the signal charges of the current frame held in the first charge holding unit are transferred to the second charge holding unit via the second transfer unit, and
signal charges generated by the second photoelectric conversion unit in the current frame are transferred to the third charge holding unit via the fourth transfer unit, signal charges of the one-previous frame held in the fourth charge holding unit are transferred to the signal output unit via the sixth transfer unit, and then the signal charges of the current frame held in the third charge holding unit are transferred to the fourth charge holding unit via the fifth transfer unit.

12. The photoelectric conversion apparatus according to claim 5, wherein
in a case where an image of one frame is captured,
signal charges generated by the photoelectric conversion unit in a first period of a current frame are transferred to the first charge holding unit via the first transfer unit, signal charges of a one-previous frame held in the second charge holding unit are transferred to the signal output unit via the third transfer unit, and then the signal charges of the current frame held in the first charge holding unit are transferred to the second charge holding unit via the second transfer unit, and
signal charges generated by the photoelectric conversion unit in a second period of the current frame are transferred to the third charge holding unit via the fourth transfer unit, signal charges of the one-previous frame held in the fourth charge holding unit are transferred to the signal output unit via the sixth transfer unit, and then the signal charges of the current frame held in the third charge holding unit are transferred to the fourth charge holding unit via the fifth transfer unit.

13. The photoelectric conversion apparatus according to claim 12, wherein
the first period and the second period have different lengths.

14. The photoelectric conversion apparatus according to claim 1, wherein
a light shielding portion is provided in at least a part of a periphery of the first charge holding unit and/or the second charge holding unit.

15. The photoelectric conversion apparatus according to claim 1, wherein
each of the plurality of pixels includes a microlens and a waveguide disposed between the microlens and the photoelectric conversion unit.

16. The photoelectric conversion apparatus according to claim 1, wherein
each of the plurality of pixels includes a charge discharge transistor that resets the photoelectric conversion unit.

17. The photoelectric conversion apparatus according to claim 1, wherein
a semiconductor chip including an electric circuit is stacked on the semiconductor substrate.

18. The photoelectric conversion apparatus according to claim 1, wherein
each of the plurality of pixels is a back-illuminated sensor including a microlens and a wiring layer disposed opposite to the microlens with respect to the photoelectric conversion unit.

19. Equipment comprising:
the photoelectric conversion apparatus according to claim 1; and
at least one of six apparatuses including:
an optical apparatus corresponding to the photoelectric conversion apparatus;
a control apparatus configured to control the photoelectric conversion apparatus;
a processing apparatus configured to process information obtained from the photoelectric conversion apparatus;
a display apparatus configured to display information obtained from the photoelectric conversion apparatus;
a storage apparatus configured to store information obtained from the photoelectric conversion apparatus; and
a mechanical apparatus configured to operate based on information obtained from the photoelectric conversion apparatus.
